(19) United States
(12) Patent Application Publication
(10) Pub. No.: US 2005/0173738 A1
(43) Pub. Date: Aug. 11, 2005

(54) Semiconductor device and manufacturing method of the same

(76) Inventors: Masao Kondo, Higashimurayama (JP); Yutaka Hoshino, Akishima (JP); Kazuhiro Ohnishi, Kodaira (JP); Isao Yoshida, Hinode (JP); Masatoshi Morikawa, Hanno (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/049,998

(22) Filed: Feb. 4, 2005

(30) Foreign Application Priority Data
Feb. 5, 2004 (JP) 2004-028828

(51) Int. Cl. H01L 29/80; H01L 21/336

(52) U.S. Cl. 257/262; 438/197

(57) ABSTRACT

Provided is a technology capable of reducing the on-resistance of a power MISFET while suppressing the generation of defects in a strained silicon layer. A strained silicon layer is formed only over an underlying strained silicon layer in the drain region by epitaxial growth. Large portions of a lightly-doped n type impurity diffusion region, offset region and heavily-doped n type impurity diffusion region are formed in these strained silicon layers, having a higher electron mobility than a conventional silicon layer.

### CROSS-REFERENCE TO RELATED APPLICATION

The present application claims priority from Japanese patent application No. 2004-028828, filed on Feb. 5, 2004, the content of which is hereby incorporated by reference into this application.

### BACKGROUND OF THE INVENTION

The present invention relates in general to a semiconductor device and to the manufacture thereof; and, more particularly, the invention relates to a technology that is effective when applied to a semiconductor device to be mounted on an RF (Radio Frequency) power module.

In recent years, a mobile communication apparatus (so-called mobile phone) using a system typified by, for example, a GSM (Global System for Mobile Communication), PCS (Personal Communication Systems), and a PDC (Personal Digital Cellular) or a CDMA (Code Division Multiple Access) system has been popular. This mobile communication apparatus has a semiconductor device built therein, and this semiconductor device is mounted on, for example, an RF (Radio Frequency) power module of a mobile communication apparatus.

A mobile communication apparatus usually has a digital signal processing unit for digital-processing sound signals or the like, an IF unit for modulating base band signals output from the digital signal processing unit to signals of an intermediate frequency, a modulation unit for modulating the signals output from the IF unit to a radio frequency, a power amplifying unit for amplifying the carrier wave of the radio frequency, and an antenna for sending signals amplified by the power amplifying unit.

As an element used in the above-described power amplifying unit, an insulating gate type field effect transistor using silicon (which will hereinafter be called a “power MISFET”) can be given as one example. This power MISFET has, on the drain side thereof, a lightly-doped drain region having a low impurity concentration; and, via this lightly-doped drain region, a heavily-doped impurity diffusion region having a high impurity concentration is formed. The power MISFET can therefore maintain a high drain withstand pressure.

Japanese Unexamined Patent Publication No. 2003-110102 (Patent Document 1) discloses a power MISFET wherein a strained silicon layer is formed over a silicon-germanium layer obtained by introducing germanium into silicon, a channel is formed in this strained silicon layer, and this strained silicon layer constitutes a portion of a source region and a portion of a drain region.

Japanese Unexamined Patent Publication No. 2002-076337 (Patent Document 2) discloses a technique for lowering the on-resistance of a power MISFET, while maintaining the drain withstand pressure, by forming, over a drain region, a trapezoidal silicon layer having an impurity introduced therein.
Patent Document 1: Japanese Unexamined Patent Publication No. 2003-110102 (pages 4 to 5, FIG. 1)
Patent Document 2: Japanese Unexamined Patent Publication No. 2002-076337 (pages 4 to 5, FIG. 1)

### SUMMARY OF THE INVENTION

In the power MISFET as described in the above-cited Patent Document 1, a strained silicon layer (about 30 nm) is formed over a silicon-germanium layer, and this strained silicon layer constitutes a portion of a drain region. The drain region is composed of a lightly doped drain region having a low impurity concentration and a heavily-doped impurity diffusion region formed outside of this lightly doped drain region. The lightly-doped drain region and the heavily-doped impurity diffusion region are formed over the strained silicon layer and silicon-germanium layer. In other words, the thickness of the lightly-doped drain region and the heavily-doped impurity diffusion region is greater than the thickness of the strained silicon layer, so that the lightly-doped drain region and the heavily-doped impurity diffusion region are formed to extend over the strained silicon layer and silicon-germanium layer lying therebelow.

The mobility of carriers moving in the strained silicon layer is about twice as much as that of carriers moving in a strain-free silicon layer. However, the mobility of carriers moving in the silicon-germanium layer is lower than that of carriers moving in the strain-free silicon layer.

The present inventors have found the following problem with the conventional power MISFET. Even if a strained silicon layer having a high carrier mobility is provided, an improvement in mobility cannot be expected from the conventional structure, which has having a large portion of a lightly-doped drain region formed in the silicon-germanium layer. It leads to an increase in the sheet resistance as a whole, resulting in a rise in the on-resistance of the power MISFET and a deterioration in the efficiency of a power amplifier having this power MISFET mounted thereon.

Thickening of the strained silicon layer can be considered as one countermeasure. This means that, in order to lower the sheet resistance of the lightly-doped drain region, a large portion of the lightly-doped drain region is formed in the strained silicon layer by thickening the strained silicon layer. The present inventors have found that, in this case, defects appear in the strained silicon layer, and this leads to an increase in the leakage current. A strained silicon layer cannot be thickened freely without forming defects therein, and it has an upper limit in its thickness (critical film thickness). When a strained silicon layer having a thickness exceeding this upper limit is formed, defects appear owing to an increased stress. When the silicon-germanium layer contains 15% of germanium and a strained silicon layer is formed over the whole surface of this silicon-germanium layer, the critical film thickness is about 30 nm.

In the conventional power MISFET, the strained silicon layer cannot be thickened further without forming defects. In other words, it is difficult when using the conventional technology to lower the sheet resistance of the lightly-doped drain region and reduce the on-resistance of a power MISFET.

An object of the present invention is to provide a technology that is capable of reducing the on-resistance of a power MISFET while suppressing the generation of defects in a strained silicon layer.

The above-described object and the other objects and novel features of the present invention will become more apparent upon consideration of the following description herein and the accompanying drawings.

An outline of typical aspects and features of the invention disclosed by the present application will be described next.

A semiconductor device having an MISFET which comprises (a) a semiconductor substrate of a first conductivity type, (b) a silicon-germanium layer of the first conductivity type formed over the semiconductor substrate, (c) a first silicon layer formed over the silicon-germanium layer, (d) a gate insulating film formed over a channel formation region in the first silicon layer, (e) a gate electrode formed over the gate insulating film, and (f) a source region and a drain region formed with the channel formation region sandwiched therebetween, wherein the drain region has a highly-doped drain region of a second conductivity type different from the first conductivity type, and a lightly-doped drain region of the second conductivity type having a lower impurity concentration than that of the highly-doped drain region and formed between the highly-doped drain region and the channel formation region; and the lightly-doped drain region contains a second silicon layer formed over the first silicon layer.

A method of manufacture of a semiconductor device according to the present invention comprises the steps of (a) preparing a semiconductor substrate by forming a silicon-germanium layer thereover, and then, forming a first silicon layer having a strain over the silicon-germanium layer, (b) forming a gate insulating film over the first silicon layer, (c) forming a gate electrode over the gate insulating film, (d) after the step (c), forming a second silicon layer having a strain over the first silicon layer in a drain formation region, and (e) introducing an impurity into the second silicon layer.

Advantages available by the typical embodiments of the invention disclosed in the present application will be described simply. The on-resistance of a power MISFET can be reduced while suppressing the generation of defects in a strained silicon layer.

### BRIEF DESCRIPTION OF THE DRAWINGS

FIG. 1 is a system block diagram of a digital cellular phone;

FIG. 2 is a plan view mainly illustrating a power MISFET according to Embodiment 1 of the present invention;

FIG. 3 is a cross-sectional view taken along a line A-A of FIG. 2;

FIG. 4 is a graph showing the relationship between the growth region width and critical thickness of a strained silicon layer;

FIG. 5 is a graph which illustrates the impurity profile and electron mobility when an offset region is formed in a conventional silicon layer having no strain;

FIG. 6 is a graph which illustrates the impurity profile and electron mobility when an offset region is formed in a silicon-germanium layer and a strained silicon layer of about 30 nm in thickness formed over the silicon-germanium layer;

FIG. 7 is a graph which illustrates the impurity profile and electron mobility when an offset region is formed in a silicon-germanium layer, a strained silicon layer of about 30 nm thick in thickness over the silicon-germanium layer, and a strained silicon layer of about 40 nm in thickness formed over the 30-nm thick strained silicon layer;

FIG. 8 is a cross-sectional view illustrating a step in the manufacture of the semiconductor device according to Embodiment 1;

FIG. 9 is a cross-sectional view illustrating a step in the manufacture of the semiconductor device following that of FIG. 8;

FIG. 10 is a cross-sectional view illustrating a step in the manufacture of the semiconductor device following that of FIG. 9;

FIG. 11 is a cross-sectional view illustrating a step in the manufacture of the semiconductor device following that of FIG. 10;

FIG. 12 is a cross-sectional view illustrating a step of the manufacture of the semiconductor device following that of FIG. 11;

FIG. 13 is a cross-sectional view illustrating a step in the manufacture of the semiconductor device following that of FIG. 12;

FIG. 14 is a cross-sectional view illustrating a step in the manufacture of the semiconductor device following that of FIG. 13;

FIG. 15 is a cross-sectional view illustrating a step in the manufacture of the semiconductor device following that of FIG. 14;

FIG. 16 is a cross-sectional view illustrating a step in the manufacture of the semiconductor device following that of FIG. 15;

FIG. 17 is a cross-sectional view illustrating a step in the manufacture of the semiconductor device following that of FIG. 16;

FIG. 18 is a cross-sectional view illustrating a step in the manufacture of the semiconductor device following that of FIG. 17;

FIG. 19 is a cross-sectional view illustrating a step in the manufacture of the semiconductor device following that of FIG. 18;

FIG. 20 is a cross-sectional view illustrating a step in the manufacture of the semiconductor device following that of FIG. 19;

FIG. 21 is a cross-sectional view illustrating a step in the manufacture of the semiconductor device following that of FIG. 20;

FIG. 22 is a cross-sectional view illustrating a step in the manufacture of a semiconductor device according to Embodiment 2;

FIG. 23 is a cross-sectional view illustrating a step in the manufacture of the semiconductor device following that of FIG. 22;

FIG. 24 is a cross-sectional view illustrating a step in the manufacture of the semiconductor device following that of FIG. 23;

FIG. 25 is a cross-sectional view illustrating a step in the manufacture of the semiconductor device following that of FIG. 24;

FIG. 26 is a cross-sectional view illustrating a step in the manufacture of the semiconductor device following that of FIG. 25;

FIG. 27 is a cross-sectional view illustrating a step in the manufacture of the semiconductor device following that of FIG. 26;

FIG. 28 is a cross-sectional view illustrating a step in the manufacture of a semiconductor device according to Embodiment 3;

FIG. 29 is a cross-sectional view illustrating a step in the manufacture of the semiconductor device following that of FIG. 28;

FIG. 30 is a cross-sectional view illustrating a step in the manufacture of the semiconductor device following that of FIG. 29;

FIG. 31 is a cross-sectional view illustrating a step in the manufacture of the semiconductor device following that of FIG. 30;

FIG. 32 is a cross-sectional view illustrating a step in the manufacture of the semiconductor device following that of FIG. 31;

FIG. 33 is a plan view mainly illustrating a power MISFET according to Embodiment 4:

FIG. 34 is a cross-sectional view taken along a line A-A of FIG. 33;

FIG. 35 is a cross-sectional view illustrating a step in the manufacture of a semiconductor device according to Embodiment 4;

FIG. 36 is a cross-sectional view illustrating a step in the manufacture of the semiconductor device following that of FIG. 35;

FIG. 37 is a cross-sectional view illustrating a step in the manufacture of the semiconductor device following that of FIG. 36;

FIG. 38 is a cross-sectional view illustrating a step in the manufacture of the semiconductor device following that of FIG. 37;

FIG. 39 is a cross-sectional view illustrating a step in the manufacture of the semiconductor device following that of FIG. 38;

FIG. 40 is a cross-sectional view illustrating a step in the manufacture of the semiconductor device following that of FIG. 39;

FIG. 41 is a plan view mainly illustrating a power MISFET according to Embodiment 5;

FIG. 42 is a cross-sectional view taken along a line A-A of FIG. 41;

FIG. 43 is a cross-sectional view illustrating a step in the manufacture of a semiconductor device according to Embodiment 5;

FIG. 44 is a cross-sectional view illustrating a step in the manufacture of the semiconductor device following that of FIG. 43;

FIG. 45 is a plan view mainly illustrating a power MISFET according to Embodiment 6;

FIG. 46 is a plan view mainly illustrating a power MISFET according to Embodiment 7;

FIG. 47 is a cross-sectional view taken along a line B-B of FIG. 46;

FIG. 48 is a cross-sectional view illustrating one example of the cause of the growth of a strained silicon layer in a step difference region;

FIG. 49 is a plan view mainly illustrating an example of a power MISFET representing a modification of Embodiment 7;

FIG. 50 is a cross-sectional view illustrating a step in the manufacture of a semiconductor device according to Embodiment 8;

FIG. 51 is a cross-sectional view illustrating a step in the manufacture of the semiconductor device following that of FIG. 50;

FIG. 52 is a cross-sectional view illustrating a step in the manufacture of the semiconductor device following that of FIG. 51;

FIG. 53 is a cross-sectional view illustrating a step in the manufacture of the semiconductor device following that of FIG. 52;

FIG. 54 is a cross-sectional view illustrating a step in the manufacture of the semiconductor device following that of FIG. 53;

FIG. 55 is a cross-sectional view illustrating a step in the manufacture of the semiconductor device following that of FIG. 54;

FIG. 56 is a plan view illustrating a step in the manufacture of a semiconductor device according to Embodiment 9;

FIG. 57 is a cross-sectional view taken along a line A-A of FIG. 56;

FIG. 58 is a cross-sectional view illustrating a step in the manufacture of the semiconductor device following that of FIG. 57;

FIG. 59 is a cross-sectional view illustrating a step in the manufacture of the semiconductor device following that of FIG. 58; and

FIG. 60 is a cross-sectional view illustrating a step in the manufacture of the semiconductor device following that of FIG. 59.

### DESCRIPTION OF THE INVENTION

Embodiments of the present invention will be described hereinafter more specifically with reference to the drawings. In all of the drawings, members of similar function will be identified by like reference numerals and overlapping descriptions thereof will be omitted.

In the following description, the subject matter of the invention may be divided in plural sections or in plural embodiments if necessary for convenience's sake. These plural sections or embodiments are not independent of each other, but are in a relation such that one is a modification, an example, represents details or is a complementary description of a part or whole of the other one, unless otherwise specifically indicated.

In the following description of the embodiments, when reference is made to a number of elements (including the number, value, amount and range), the number is not limited to a specific number, but can be greater than or less than the specific number, unless otherwise specifically indicated, or unless it is principally apparent that the number is limited to the specific number.

Moreover in the following description of the embodiments, it is needless to say that the constituting elements (including element steps) are not always essential unless otherwise specifically indicated, or unless it is principally apparent that they are essential.

Similarly, in the following description of the embodiments, when a reference is made to the shape or positional relationship of the constituting elements, a shape or relationship substantially analogous or similar to it is also embraced, unless otherwise specifically indicated, or unless it is principally apparent that it is not. This also applies to the above-described value and range.

In the plan views used to illustrate the below-described embodiments, a view of interconnection portions (a structure above an interlayer insulating film) of a power MISFET may be omitted and some of them may be partially hatched for facilitating an understanding of the subject matter. In a plan view used to illustrate the below-described embodiments, some regions are hatched, but hatching in the plan view does not indicate that it is a cross-section.

### Embodiment 1

In Embodiment 1, the present invention is applied to a semiconductor device to be mounted on a power amplifier in a digital cellular phone.

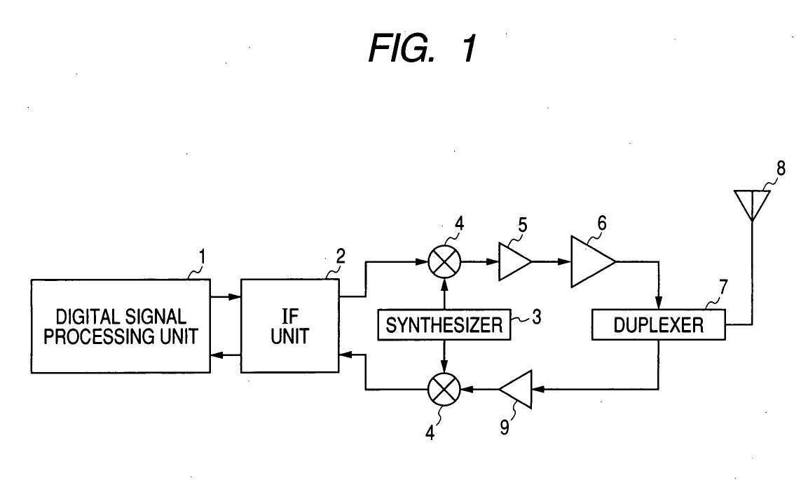

FIG. 1 is a system block diagram of a digital cellular phone, in which a digital signal processing unit 1, an IF (Intermediate Frequency) unit 2, a synthesizer 3, a mixer 4, a driver 5, a power amplifier 6, a duplexer 7, an antenna 8 and a low noise amplifier 9 are illustrated.

In the digital signal processing unit 1, baseband signals are generated by digital processing of analogue signals, such as sound signals, while the IF unit 2 converts the baseband signals generated in the digital signal processing unit 1 into signals of an intermediate frequency.

The synthesizer 3 is a circuit used for synthesizing frequencies by using a reference oscillator, such as a quartz oscillator whose frequency is stable, thereby obtaining a desired frequency with high accuracy. The mixer 4 is a frequency converter for converting the frequency.

The driver 5 is a circuit used for amplifying signals, while the power amplifier 6 is a circuit used for generating signals, which are larger copies of low-level input signals, by the power fed from a power source.

The duplexer 7 separates signals that are input into a digital cellular phone from signals output from the digital cellular phone.

The antenna 8 receives or emits radio waves, while the low noise amplifier 9 amplifies signals received by the antenna 8.

A digital cellular phone has the above-described constitution. Its operation will be described briefly. First, emission of radio waves from the digital cellular phone will be described. A baseband signal generated by the digital processing of an analogue signal, such as a sound signal, at the digital signal processing unit 1 is converted into an intermediate-frequency signal at the IF unit 2. The intermediate-frequency signal is then converted into a radio-frequency signal by the synthesizer 3 and mixer 4. The signal converted into the radio frequency signal is amplified by the driver 5, and it is then input to the power amplifier 6. The radio-frequency signal input to the power amplifier 6 is amplified further by the power amplifier, followed by transmission of the signal from the antenna 8 via the duplexer 7.

Next, radio reception will be described. A radio-frequency signal received by the antenna 8 is amplified by the low noise amplifier 9. The amplified signal from the low noise amplifier 9 is then converted into an intermediate-frequency signal by the synthesizer 3 and mixer 4, followed by input of the signal to the IF unit 2. At the IF unit 2, detection of the intermediate-frequency signal is performed and a baseband signal is extracted. This baseband signal is processed at the digital signal processing unit 1, and a sound signal is output.

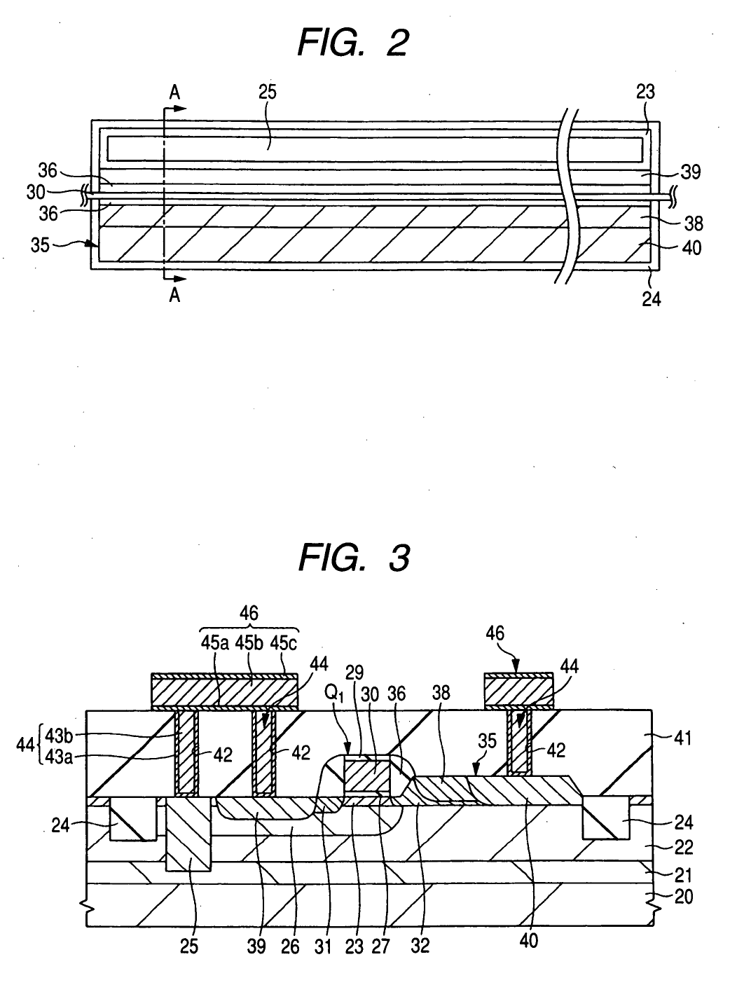

For the power amplifier 9 of such a digital cellular phone, a power MISFET is employed. The constitution of the power MISFET according to Embodiment 1 is shown in FIGS. 2 and 3. FIG. 2 is a plan view illustrating the power MISFET according to Embodiment 1, while FIG. 3 is a cross-sectional view taken along a line A-A of FIG. 2.

In FIG. 2, the region where the power MISFET is formed is encompassed, at the periphery thereof, by an element isolation region 24; and, in an active region encompassed by the element isolation region 24, a strained silicon (first silicon) layer 23 is formed. In the central part of the active region, a gate electrode 30, extending from the left side to the right side, is formed. Of regions separated by the gate electrode 30 traversing this central part, an upper region as seen in the drawing is a source region, while a lower region is a drain region.

On both sides of the gate electrode 30, side walls 36 are formed. In the source region, a heavily-doped n-type impurity diffusion region (heavily-doped source region) 39 and a conducting region 25, which are semiconductor regions, are formed on the outside of the side wall 36. In the drain region, an offset region (a portion of a lightly-doped drain region) 38 and a heavily-doped n-type impurity diffusion region (heavily-doped drain region) 40, which are semiconductor regions, are formed outside of the side wall 36. The offset region 38 and heavily-doped n-type impurity diffusion region 40 are mainly formed in the strained silicon layer 23 and a strained silicon layer 35 (second silicon layer) formed over the strained silicon layer 23. In FIG. 2, the region where the strained silicon layer 35 is formed is hatched in order to facilitate an understanding of the subject matter. The strained silicon layer 35 is formed only over the strained silicon layer 23 in the drain region so that the drain region having the strained silicon layer 35 formed thereover protrudes compared with the source region having no strained silicon layer 35 formed thereover. In other words, the hatched drain region is higher than the source region.

FIG. 3, which is a cross-sectional view taken along a line A-A of FIG. 2, will be explained next. In FIG. 3, a silicon-germanium layer 21, which is doped relatively heavily with an impurity, is formed over a semiconductor substrate (semiconductor substrate having a first conductivity type) 20 having a p type impurity introduced therein. Over the silicon-germanium layer 21, a silicon-germanium layer 22 is formed having an impurity introduced therein at a relatively low concentration. The silicon-germanium layers 21 and 22 are composed of, for example, about 85% of silicon atoms and about 15% of germanium atoms.

Over the silicon-germanium layer 22, a strained silicon layer 23 is formed. The spacing between crystal lattices of the silicon-germanium layer 22 is made wider than that between crystal lattices of silicon by the introduction of germanium atoms. A silicon layer formed over the silicon-germanium layer 22 becomes strained by a tensile stress generated to conform to the lattice spacing of the silicon-germanium layer 22. The strained silicon layer 23 is therefore formed over the silicon-germanium layer 22. The silicon-germanium layers 21 and 22 are thus disposed for the formation of the strained silicon layer 23. The strained silicon layer 23 has a thickness of, for example, 30 nm.

In the semiconductor substrate 20 having the silicon-germanium layers 21 and 22, and the strained silicon layer 23 formed thereover, an element isolation region 24 is formed. In the active region within this element isolation region 24, a conducting region 25, p-well 26 and power MISFETQ₁ are formed. The conducting region 25 is formed to communicate between the source region of the power MISFETQ₁ and the silicon-germanium layer 21. The p-well 26 extends over the silicon-germanium layer 22 and the strained silicon layer 23.

The constitution of the power MISFETQ₁ will be described next. The power MISFETQ₁ has a gate insulating film 27 formed over the channel formation region of the strained silicon layer 23 and a gate electrode 30 formed over the gate insulating film 27. A cap insulating film 29 is formed over the gate electrode 30, and side walls 36 are formed over the side surfaces of the gate electrode 30.

On the left side of the gate electrode 30, a source region is formed, while on the right side of the gate electrode 30, a drain region is formed. In other words, the source region and drain region are formed with the channel formation region of the strained silicon layer 23 sandwiched therebetween. In the drain region formed on the right side of the gate electrode 30, a strained silicon layer 35 is formed over the strained silicon layer 23. As illustrated in FIG. 3, the drain region having the strained silicon layer 35 formed therein is higher than the source region having no strained silicon layer 35 formed therein, and it protrudes in a trapezoidal form. The strained silicon layer 35 has a thickness of, for example, about 40 nm.

The source region has an n type impurity diffusion region 31 formed in alignment with the gate electrode 30 and a heavily-doped n type impurity diffusion region (heavily-doped source region) 39 formed in alignment with the side wall 36. The drain region, on the other hand, has a lightly-doped n type impurity diffusion region 32 formed in alignment with the gate electrode 30, an offset region 38 formed in alignment with the side walls 36 and a heavily-doped n type impurity diffusion region 40 formed outside this offset region 38. The lightly-doped n type impurity diffusion region 32 and offset region 38 constitute a lightly-doped drain region, while the heavily-doped n type impurity diffusion region 40 constitutes a heavily-doped drain region. Of the lightly-doped n type impurity diffusion region 32, offset region 38 and heavily-doped n type impurity diffusion region 40, the lightly-doped n type impurity diffusion region 32, which is nearest to the gate electrode 30, has the least impurity concentration, while the heavily-doped n type impurity diffusion region 40, which is most distant from the gate electrode 30, has the highest impurity concentration.

According to the power MISFETQ₁ of Embodiment 1 having the above-described constitution, the strained silicon layer 35 is formed over the strained silicon layer 23 in the drain region. The total thickness of the strained silicon layers can therefore be thickened. Even if small portions of the lightly-doped n type impurity diffusion region 32, offset region 38 and heavily-doped n type impurity diffusion region 40 in the drain region are formed in the silicon-germanium layer 22 below the strained silicon layer 23, the remaining large portions can be formed in the strained silicon layer 23 and strained silicon layer 35. Particularly, the strained silicon layer 35 has a thickness of about 40 nm, thicker than the strained silicon layer 23, which is about 30 nm thick. This facilitates the formation of most of the drain region in the strained silicon layer 23 and strained silicon layer 35.

The lightly-doped n type impurity diffusion region 32, offset region 38 and heavily-doped n type impurity diffusion region 40 are each formed by the introduction of an impurity. In the conventional structure having no strained silicon layer 35 over the strained silicon layer 23, the strained silicon layer 23 is only one strained silicon layer. The thickness of only the strained silicon layer 23 is not enough for forming all of the lightly-doped n type impurity diffusion region 32, offset region 38 and heavily-doped n type impurity diffusion region 40 in the strained silicon layer 23, and most of them are formed in the silicon-germanium layer 22 formed below the strained silicon layer 23.

In a silicon layer having a strain, electron mobility is about twice as much as that of a commonly-used strain free silicon layer. The electron mobility in the silicon-germanium layer becomes lower than that of the commonly-used silicon layer. In the conventional structure without strained silicon layer 35 over the strained silicon layer 23, large portions of the lightly-doped n type impurity diffusion region 32, offset region 38 and heavily-doped n type impurity diffusion region 40 are therefore formed in the silicon-germanium layer 22 having lower electron mobility than the strained silicon layer 23 having higher electron mobility. As a result, even the formation of the strained silicon layer 23 does not contribute to an improvement in the silicon electron mobility, making it difficult to attain a drastic reduction in the sheet resistance.

According to the power MISFETQ₁ of Embodiment 1, on the other hand, large portions of the lightly-doped n type impurity diffusion region 32, offset region 38 and heavily-doped n type impurity diffusion region 40 can be formed in the strained silicon layer 23 and strained silicon layer 35, each having a high electron mobility, so that a drastic reduction in the sheet resistance owing to an improvement in the electron mobility can be attained. Such a reduction in the sheet resistance leads to a reduction in the on-resistance of the power MISFETQ₁. As a result, a power amplifier having this power MISFETQ₁ mounted thereon has an improved efficiency.

In the power MISFETQ₁ of this Embodiment 1, a lightly-doped drain region existing between the gate electrode 30 and heavily-doped n type impurity diffusion region 40 has a dual structure, in which the lightly-doped n type impurity diffusion region 32 nearest to the gate electrode 30 has a relatively low impurity concentration and the offset region 38 farthest from the gate electrode 30 has a relatively high impurity concentration.

This structure widens a depletion layer between the gate electrode 30 and drain region, resulting in a decrease in the feedback capacitance formed between the gate electrode 30 and lightly-doped n type impurity diffusion region 32. Moreover, since the impurity concentration of the offset region 38 is relatively high, the on-resistance of the power MISFETQ₁ decreases. The offset region 38 is formed at a distance from the gate electrode 30, so that it has little influence on the feedback capacitance. With use of the power MISFETQ₁ of Embodiment 1, both the feedback capacitance and on-resistance can be decreased, and as a result, the efficiency of the power amplifier can be improved further.

In the power MISFETQ₁ of Embodiment 1, the junction area between the p well 26 and drain region is small. The junction between the p well 26 and drain region is conducted only between the p well 26 and the lightly-doped n type impurity diffusion region 32 having a low impurity concentration. With use of the power MISFETQ₁ of Embodiment 1, therefore, the withstand pressure of pn junction between the p well 26 and drain region can be improved.

As illustrated in FIG. 3, a silicon oxide film 41, which an interlayer insulating film, is formed over the power MISFETQ₁. The silicon oxide film 41 has a contact hole 42 formed therein. In the contact hole 42, a titanium/titanium nitride film 43a and tungsten film 43b are filled to form a plug 44. Over the plug 44, an interconnection 46 made of a titanium/titanium nitride film 45a, an aluminum film 45b and a titanium/titanium nitride film 45c is formed. For example, by this plug 44 and interconnection 46, the heavily-doped n type impurity diffusion region 39 and conducting region 25, which partly constitute the source region of the power MISFETQ₁, are electrically connected.

Next, a reason for the formation of the strained silicon layer 35 only over the drain region in the power MISFETQ₁ of Embodiment 1 will be described. As a method of forming large portions of the lightly-doped n type impurity diffusion region 32, offset region 38 and heavily-doped n type impurity diffusion region 40 in a strained silicon layer, simple thickening of the strained silicon layer 23 formed over the silicon-germanium layer 22 can be considered.

However, present inventors have found that, in this case, defects appear in the strained silicon layer 23, which causes an increase in the leakage current and a deterioration in the electron mobility due to these defects. It is impossible to freely thicken the strained silicon layer 23 without causing defects and the thickness of the strained silicon layer 23 has an upper limit (critical film thickness). When a strained silicon layer with a thickness exceeding this upper limit is formed, an increase in stress leads to a generation of defects.

It has been found as a result of a test that when a strained silicon layer is caused to grow in a minute island region, defects do not appear easily compared with the case in which a strained silicon layer is caused to grow all over a semiconductor substrate. Suppression of generation of defects upon the growth of a strained silicon layer in such a minute region is presumed to occur because the stress of a strained silicon layer which has grown tends to be relaxed by a partial strain of an underground region below the growth region. More specifically, when only the strained silicon layer over the drain formation region is thickened by, for example, selective epitaxial growth, defects do not appear easily compared with the case where a strained silicon layer is caused to grow with an equal thickness over the whole surface of the semiconductor substrate, which reduces the leakage current due to these defects. For this reason, the strained silicon layer 35 is formed only over the drain formation region in the power MISFETQ₁ of Embodiment 1. In particular, the strained silicon layer 35 is not formed over the source formation region in this Embodiment 1 so that the growth region of the strained silicon layer 35 can be narrowed and generation of defects in the strained silicon layer 35 can be reduced further.

FIG. 4 illustrates the relationship between the size of a region in which a strained silicon layer is caused to grow and the upper limit (critical film thickness) of the thickness of the strained silicon layer which can be formed without defects. Plotted along the abscissa in FIG. 4 is an area of a rectangular region which is 50 μm on one side and the width of a growth region on the other side. For example, when the width of the growth region plotted along the abscissa is 1 μm, a strained silicon layer is caused to grow in an area of 50 μm×1 μm. When the width of the growth region plotted along the abscissa is 1000 μm, a strained silicon layer is caused to grow in an area of 50 μm×1000 μm. The critical film thickness of a strained silicon layer which can be formed without generating defects is shown along the ordinate.

As is apparent from FIG. 4, when the width of the growth region is 1000 μm, the critical film thickness of the strained silicon layer is about 35 nm. When the width of the growth region is 3 μm and is approximate to the width of the drain region of the power MISFETQ₁, on the other hand, the critical film thickness of the strained silicon layer reaches even about 80 nm. By causing the strained silicon layer 35 to grow only over the drain formation region as provided in Embodiment 1, the strained silicon layer 35 of about 40 nm can be formed over the strained silicon layer 23 of about 30 nm without generating defects. As a result, large portions of the lightly-doped n type impurity diffusion region 32, offset region 38 and heavily-doped n type impurity diffusion region 40 constituting the drain region can be formed, without causing defects, in the strained silicon layer 23 and strained silicon layer 35 having a high electron mobility. This makes it possible to lower the sheet resistance of the drain region without increasing the leakage current.

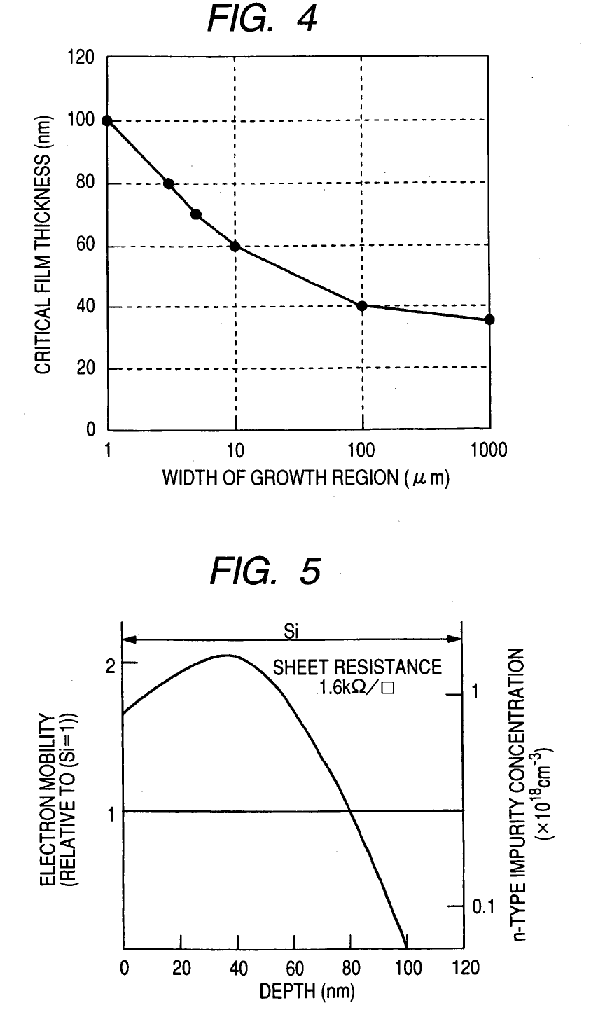

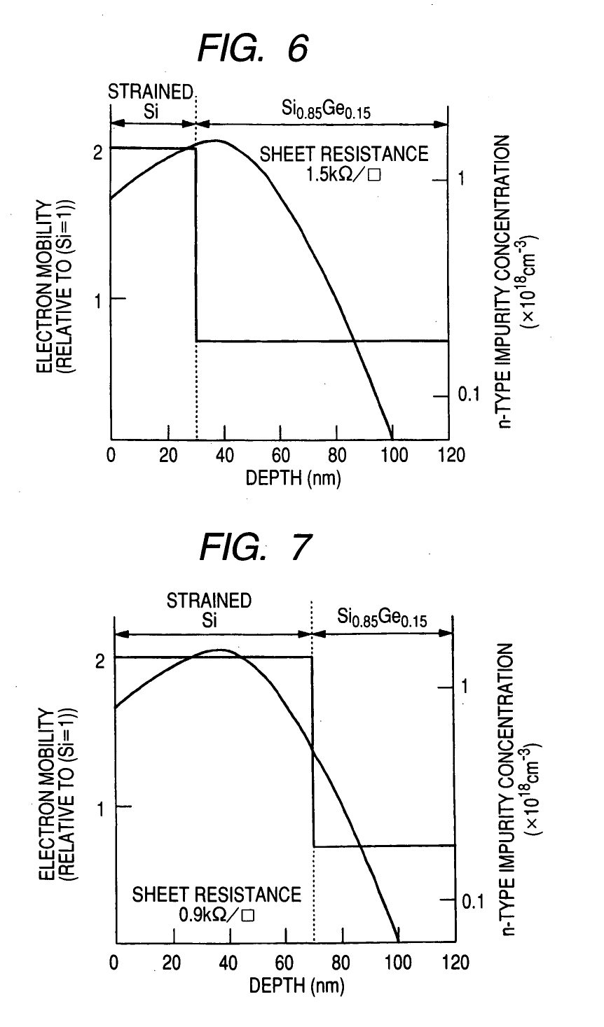

The degree of lowering of the sheet resistance in Embodiment 1 can be estimated as described below. FIG. 5 illustrates the impurity profile and electron mobility when an offset region (a portion of a lightly-doped drain region) is formed in a conventional strain-free silicon layer. FIG. 6 illustrates the impurity profile and electron mobility when an offset region is formed in a silicon-germanium layer and a strained silicon layer of about 30 nm in thickness formed over the silicon-germanium layer. FIG. 7 illustrates an impurity profile and electron mobility when an offset region is formed in a silicon-germanium layer, a strained silicon layer of about 30 nm in thickness formed over the silicon-germanium layer, and a strained silicon layer of about 40 nm in thickness formed over the strained silicon layer of about 30 nm in thickness.

In each of FIGS. 5, 6 and 7, the depth from the surface is plotted along the abscissa and its unit is in nm. Of two ordinates, that on the left side shows a relative mobility supposing that the electron mobility in the conventional silicon layer is 1, and that on the right side shows the concentration of an n type impurity in the offset region.

In FIG. 5, the offset region is formed in a strain-free silicon layer so that the electron mobility in the offset region is 1. The concentration of an n type impurity in the offset region gradually rises as the depth increases from 0 nm. The n type impurity concentration at the depth of about 40 nm exceeds 1.0×10¹⁸ cm⁻³ and reaches a peak. As the depth increases further from the depth of about 40 nm, the n type impurity concentration lowers. At the depth of about 100 nm, the concentration becomes 0.1×10¹⁸ cm⁻³ or lower. This suggests the formation of the offset region to the depth of about 100 nm. The sheet resistance of the offset region is proportional to the reciprocal of the integral of (n type impurity concentration x electron mobility) in the depth direction. As a result of a calculation based on this equation, the sheet resistance is 1.6 kΩ/□.

In FIG. 6, the impurity profile of the offset region is similar to that illustrated in FIG. 5 and the offset region is formed with a depth of about 100 nm. In this offset region, the strained silicon layer is formed from the depth of 0 nm to the depth of about 30 nm, so that the electron mobility up to this depth is about 2. At a position deeper than the depth of 30 nm, the silicon-germanium layer is formed so that, at the depth of 30 nm or greater, the electron mobility is less than 1, which is lower than that of the conventional silicon layer. The existence of a peak of the n type impurity concentration at the depth of about 40 nm suggests that more than half of n type impurities exist in the silicon-germanium layer. Calculation of the sheet resistance based on the above-described equation results in 1.5 kΩ/□. Even if the strained silicon layer of about 30 nm thick is laid over the silicon-germanium layer, more than half of the offset region is formed in the silicon-germanium layer, suggesting that improvement in the mobility of the whole offset region is not as large as expected.

In FIG. 7, the impurity profile of the offset region is similar to that shown in FIG. 5 or FIG. 6, and the offset region is formed with a depth of about 100 nm. In Embodiment 1, the strained silicon layer is formed from the depth of 0 nm to the depth of 70 nm so that the electron mobility within this range is about 2. At a position deeper than the depth of 70 nm, the silicon-germanium layer is formed so that the mobility at the depth of 70 nm or greater, the electron mobility becomes less than 1. Judging from the existence of the peak of the n type impurity concentration at the depth of about 40 nm, the peak exists within the strained silicon layer. As can be understood from FIG. 7, the strained silicon layer extends from the depth of 0 nm to the depth of 70 nm, meaning that a large portion (at least about 80%) of the n type impurities exists in the strained silicon layer having a high mobility. From this, a lowering in sheet resistance can be expected. A calculation based on the above-described equation results in a sheet resistance of 0.9 kΩ/□. In this Embodiment 1, a large portion of the offset region can be formed in the strained silicon layer, so that the sheet resistance can be lowered compared with that shown in FIG. 6. More specifically, the sheet resistance can be lowered by about 40% compared with that shown in FIG. 6, which enables about a 30% reduction in the on-resistance of the power MISFETQ₁, and about a 5% improvement in the efficiency of a power amplifier.

Following are specific examples of the formation of a large portion of the offset region in the strained silicon layer. For example, in Embodiment 1, the strained silicon layer is formed with a depth of about 70 nm and the peak of the impurity concentration exists at the depth of about 40 nm. In the impurity profile of the offset region, the existence of a peak of the impurity concentration in the strained silicon layer can be considered as one example of the existence of a large portion of the offset region in the strained silicon layer.

As illustrated in FIG. 7, about 80% or greater impurities exist in the strained silicon layer in Embodiment 1. It is therefore preferred that about 80% or greater of the impurities exist in the strained silicon layer. However, the existence of the peak of the impurity concentration in the strained silicon layer is given above as one example of the existence of a large portion of the offset region within the strained silicon layer. The peak of the impurity concentration exists in the strained layer, in other words, in consideration that the impurity concentration is roughly symmetrical relative to the peak, at least a half of the impurities exist in the strained silicon layer. Accordingly, the existence of more than half of the impurities in the offset region can be given as one example of the existence of the offset region in the strained silicon layer.

In Embodiment 1, as illustrated in FIG. 7, the thickness of the offset region is about 100 nm, while the thickness of the strained silicon layer is about 70 nm. The existence of a half (depth: 50 nm) of the thickness of the offset region in the strained silicon layer can also be given as one example of the existence of a large portion of the offset region in the strained silicon layer.

A method of manufacture of the power MISFETQ₁ in Embodiment 1 will be explained next with reference to the drawings.

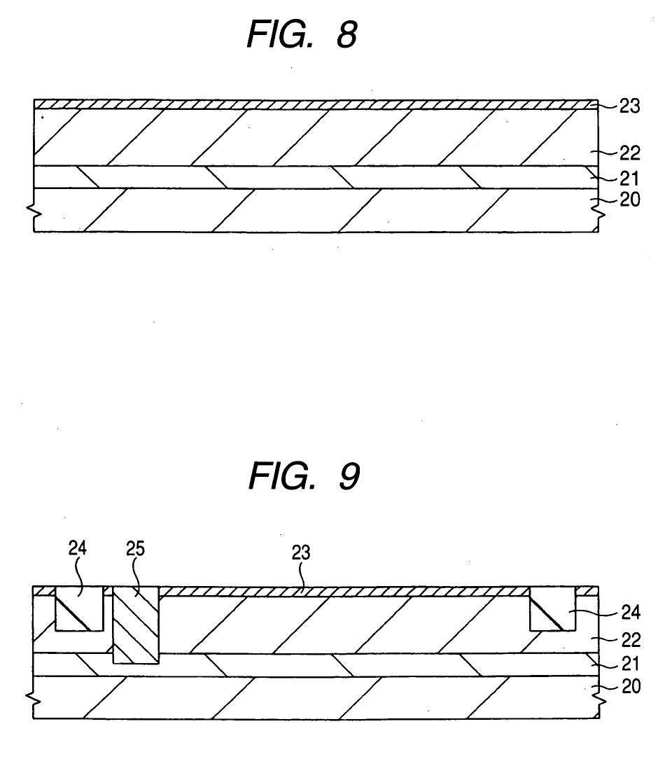

As illustrated in FIG. 8, a silicon-germanium layer 21 having a p type impurity introduced therein at a relatively high concentration is formed over the main surface of a semiconductor substrate 20, which is made of p type single crystal silicon, by utilizing epitaxial growth. Over this silicon-germanium layer 21, a silicon-germanium layer 22 having a p type impurity introduced therein at a relatively low concentration is formed utilizing epitaxial growth. These silicon-germanium layers 21 and 22 are each composed of, for example, about 85% of silicon atoms and about 15% of germanium atoms.

Over the silicon-germanium layer 22, a strained silicon layer 23 of about 30 nm in thickness is formed by utilizing epitaxial growth. The lattice spacing of the silicon-germanium layer 22 is wider than that of a silicon layer. This means that the silicon layer formed over the silicon-germanium layer 22 is strained because the lattice spacing of the silicon layer attempts to align with that of the silicon-germanium layer 22, thereby to produce a tensile strain. The strained silicon layer 23 is therefore formed over the silicon-germanium layer 22.

As illustrated in FIG. 9, a conducting region 25 is formed to provide conduction between the surface and the silicon-germanium layer 21. The conducting region 25 having a hole filled with a polysilicon film can be formed, for example, by forming a hole starting from the surface of the strained silicon layer 23 and reaching the silicon-germanium layer 21 by utilizing photolithography and etching and then forming a polysilicon film so as to fill the hole therewith, for example, by using CVD (Chemical Vapor Deposition).

An element isolation region 24 for providing a separation between elements is then formed. This element isolation region 24 is formed in the following manner. First, an element isolating trench is formed using photolithography and etching. The interior of the element isolating trench is then oxidized by thermal oxidation. Upon oxidization, thermal treatment is conducted for 20 minutes, while adjusting the temperature to 950° C. Over the element isolating trench and strained silicon layer 23, a silicon oxide film is formed, for example, by CVD, followed by the removal of the silicon oxide film formed over the strained silicon layer 23 by CMP (Chemical Mechanical Polishing) to leave the silicon oxide film only in the element isolating trench. The element isolation region 24 can be formed in such a manner.

As illustrated in FIG. 10, a p well 26 is formed using photolithography and ion implantation. The p well 26 is formed by introducing a p type impurity, such as boron or boron fluoride. After the introduction of the p type impurity, heat treatment is conducted to activate the p type impurity thus introduced. This heat treatment is performed for 10 seconds at a temperature adjusted to 950° C.

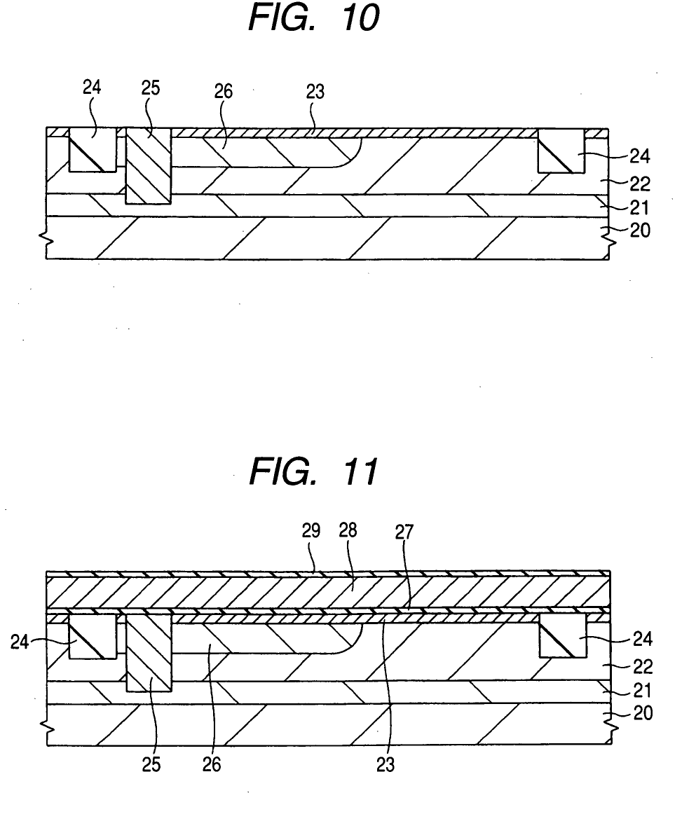

After washing the surface of the strained silicon layer 23 with hydrofluoric acid, a gate insulating film 27 is formed over the strained silicon layer 23, as illustrated in FIG. 11. The gate insulating film 27 is made of, for example, a silicon oxide film and can be formed, for example, by thermal oxidation. As the gate insulating film 27, an oxynitride film, which is a silicon oxide film containing nitrogen, can be used instead of the silicon oxide film. Use of it makes it possible to reduce trapping of hot electrons on the interface of the gate insulating film 27. Alternatively, it is also possible to form a silicon oxide film by CVD over the silicon oxide film formed by thermal oxidation and to constitute the gate insulating film 27 by these two silicon oxide films.

Over the gate insulating film 27, a polysilicon film 28 and a cap insulating film 29 made of a silicon oxide film are deposited successively. The polysilicon film 28 and the cap insulating film 29 can be formed, for example, by CVD.

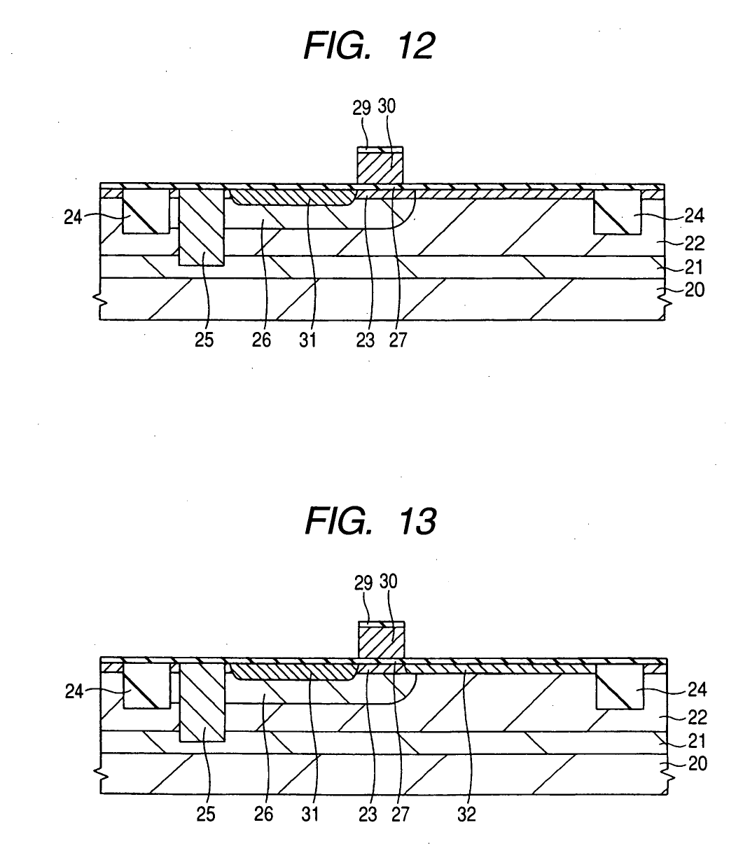

As illustrated in FIG. 12, the polysilicon film 28 is patterned using photolithography and dry etching to form a gate electrode 30. An n type impurity diffusion region 31, which will constitute a part of a source region, is formed using photolithography and ion implantation. This n type impurity diffusion region 31 is formed in alignment with the gate electrode 30. The n type impurity diffusion region 31 is formed by introducing an n type impurity by ion implantation and heat treating to activate the n type impurity thus introduced. This heat treatment is conducted for 10 seconds at a temperature adjusted to 950° C.

As illustrated in FIG. 13, a lightly-doped n type impurity diffusion region 32, which will constitute a part of a drain region, is formed by photolithography and ion implantation. This lightly-doped n type impurity diffusion region 32 is formed in alignment with the gate electrode 30. The lightly-doped n type impurity diffusion region 32 is formed by introducing an n type impurity by ion implantation and heat treating to activate the n type impurity thus introduced. The n type impurity reaches the silicon-germanium layer 22 lying below the strained silicon layer 23, but the amount of the n type impurity introduced in the silicon-germanium layer 22 is much smaller than that introduced in the strained silicon layer 23, so that, as seen in the drawing, the lightly-doped n type impurity diffusion region 32 seems to exist in the strained silicon layer 23.

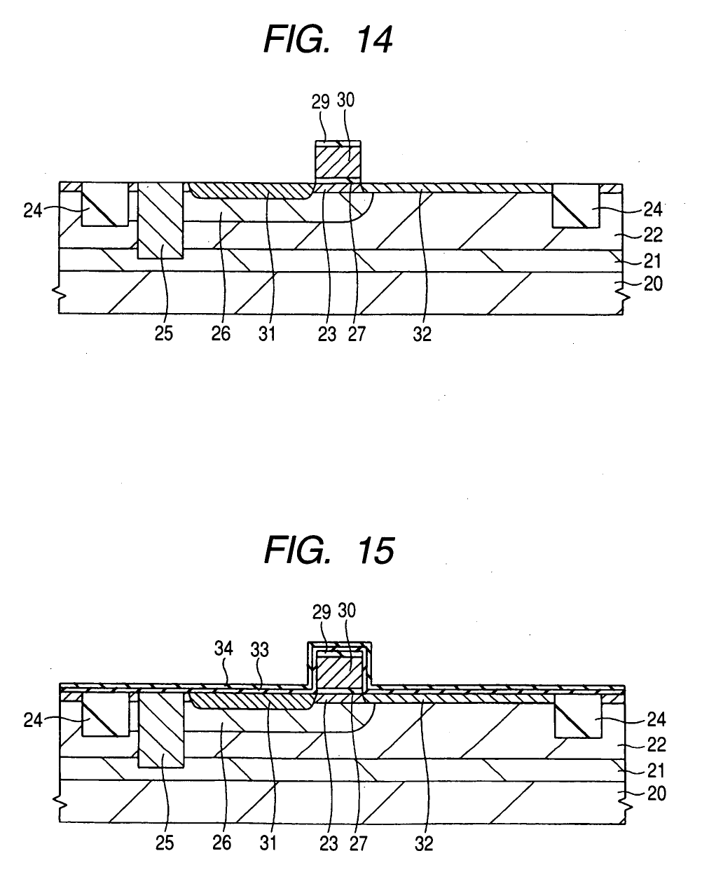

As illustrated in FIG. 14, after removal of the gate insulating film 27 exposed from the main surface of the semiconductor substrate 20, a silicon oxide film 33 and a silicon nitride film 34 are successively formed over the main surface of the semiconductor substrate 20, as illustrated in FIG. 15. The silicon oxide film 33 and silicon nitride film 34 can be formed, for example, by CVD.

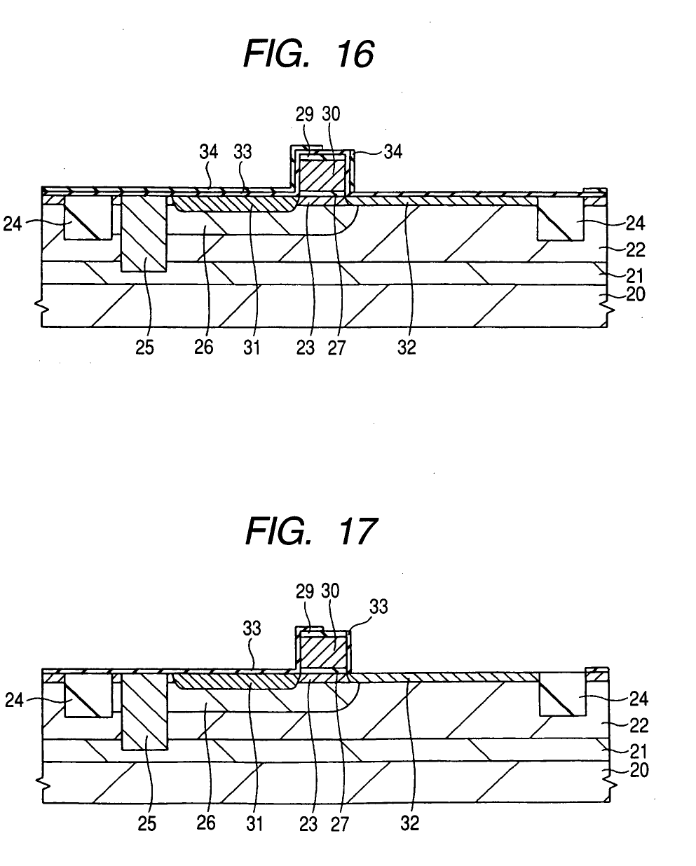

As illustrated in FIG. 16, the silicon nitride film 34 is patterned using photolithography and anisotropic etching. The patterning is conducted to make an opening in the film for almost the whole drain formation region. The silicon nitride film 34 is etched by anisotropic etching so that the silicon nitride film 34 remains on the side walls of the gate electrode 30. By wet etching using the patterned silicon nitride film 34 as a mask, the silicon oxide film 33 formed over the drain formation region is removed. The patterned silicon nitride film 34 is then removed by wet etching, as illustrated in FIG. 17.

Wet etching using the patterned silicon nitride film 34 as a mask is employed here as a method of etching the silicon oxide film 33 formed over the drain formation region, while leaving the silicon oxide film 33 over the side walls of the gate electrode 30. Use of this method has the following advantages.

As a method of removing the silicon oxide film 33 formed over the drain formation region, while leaving the silicon oxide film 33 over the side walls of the gate electrode 30, a method of not using the patterned silicon nitride film 34, but forming a patterned resist film over the silicon oxide film 33 and then removing the silicon oxide film 33 directly by anisotropic etching, can be considered. In other words, by anisotropic dry etching of the silicon oxide film 33, the silicon oxide film 33 formed over the drain formation region is removed, while leaving the silicon oxide film over the side walls of the gate electrode. In this method, however, the silicon oxide film 33 over the drain formation region is removed by dry etching, and this damages the strained silicon layer 23 (lightly-doped n type impurity diffusion region 32) lying under the silicon oxide film 33.

In this Embodiment 1, the silicon oxide film 33 over the drain formation region is removed by wet etching using the patterned silicon nitride film 34 as a mask. In this embodiment 1, wet etching is employed for the removal of the silicon oxide film 33 over the drain formation region, so that it is possible to suppress the damage to the underlying strained silicon layer 23 which will otherwise occur by dry etching.

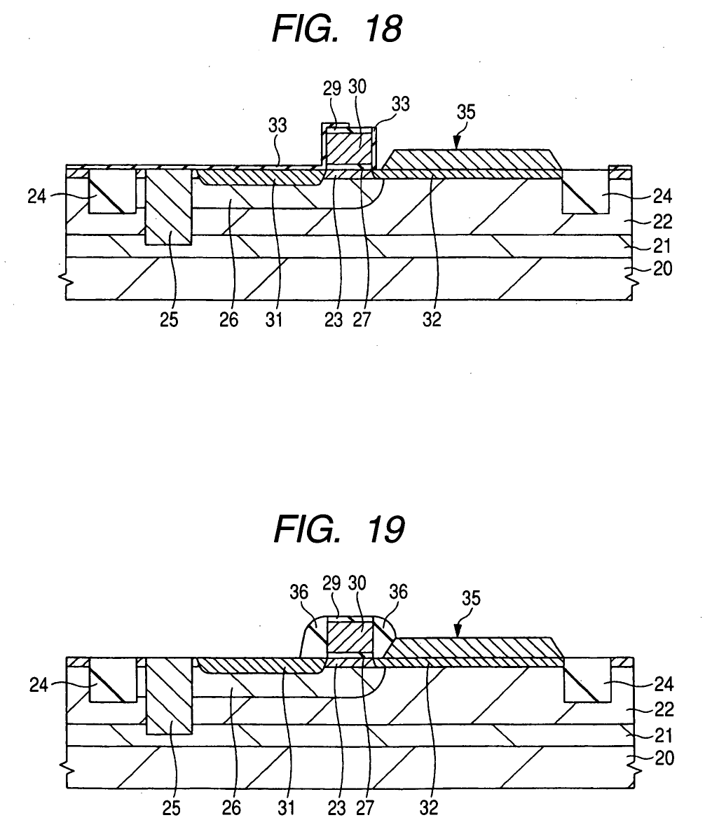

As illustrated in FIG. 18, a strained silicon layer 35 of about 40 nm in thickness is formed selectively over the strained silicon layer 23 (lightly-doped n type impurity diffusion region 32) of the drain formation region by using epitaxial growth. A silicon layer is formed over the strained silicon layer 23 that this silicon layer is also strained. By using epitaxial growth in this manner, the strained silicon layer 35 can be formed selectively over the strained silicon layer 23 (lightly-doped n type impurity diffusion region 32) which is exposed.

The strained silicon layer 35 is not formed over the whole surface of the semiconductor substrate 20, but is formed only over the drain formation region, so that its area is narrow. The strained silicon layer which can be formed without defects can be made thicker compared with the formation thereof over the whole surface of the semiconductor substrate 20. The critical thickness of a strained silicon layer which can be formed in an area as narrow as the drain formation region is about 80 nm. In this case, in the drain formation region, the total thickness of the strained silicon layer 23 and strained silicon layer 35 formed thereover is about 70 nm. The total thickness of the strained silicon layers (strained silicon layer 23 and strained silicon layer 35) formed over the drain formation region is not greater than the critical film thickness, so that the strained silicon layer 35 with reduced defects can be formed.

In this Embodiment 1, the strained silicon layer 23 has a thickness of about 30 nm, while the strained silicon layer 35 formed thereover has a thickness of about 40 nm. Compared with the thickness of the strained silicon layer 23, the strained silicon layer 35 obtained by selective epitaxial growth is thicker. Defects tend to appear when the first strained silicon layer 23 is thicker. The first strained silicon layer 23 is formed all over the main surface of the semiconductor substrate 20, so that its critical film thickness is low. If the strained silicon layer 23 is thickened, defects tend to occur. It is to be noted that since the silicon oxide film 33 is formed over the side walls of the gate electrode 30, silicon does not grow thereon.

As illustrated in FIG. 19, after formation of a silicon oxide film over the main surface of the semiconductor substrate 20, for example, by CVD, the resulting silicon oxide film is subjected to anisotropic dry etching, whereby side walls 36 are formed over the side surfaces of the gate electrode 30.

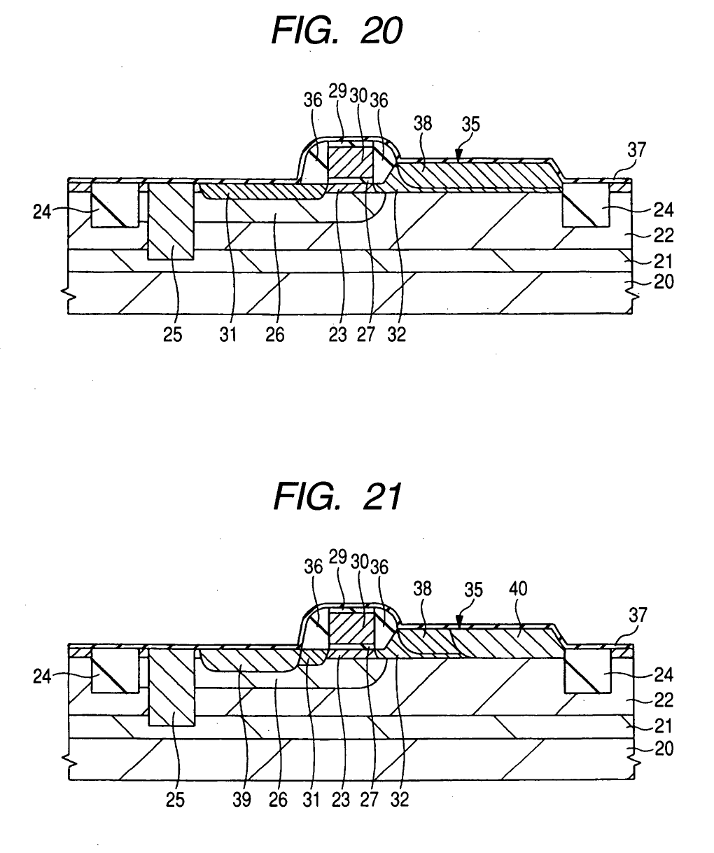

As illustrated in FIG. 20, a silicon oxide film 37 is formed over the main surface of the semiconductor substrate 20, for example, by CVD. By photolithography and ion implantation, an offset region 38 is formed in alignment with the side walls 36. The offset region 38 is formed by introducing an n type impurity, such as phosphorus or arsenic, into the strained silicon layer 35 or strained silicon layer 23 (lightly-doped n type impurity diffusion region 32). The n type impurity thus introduced is activated by heat treatment. The n type impurity reaches the silicon-germanium layer 22 lying below the strained silicon layer 23 (lightly-doped n type impurity diffusion region 32), but the amount of the n type impurity introduced into the silicon-germanium layer 22 is much smaller than that introduced into the strained silicon layer 35 or strained silicon layer 23 (lightly-doped n type impurity diffusion region 32) so that, as seen in the drawing, the offset region 38 seems to exist in the strained silicon layer 35 and strained silicon layer 23 (lightly-doped n type impurity diffusion region 32). The n type impurity is introduced into the offset region 38 at a higher concentration than that in the lightly-doped n type impurity diffusion region 32.

As illustrated in FIG. 21, a heavily-doped n type impurity diffusion region 39 constituting a part of the source region and a heavily-doped n type impurity diffusion region 40 constituting a part of the drain region are formed using photolithography and ion implantation. The heavily-doped n type impurity diffusion region 39 has an n type impurity introduced therein at a higher concentration than the n type impurity diffusion region 31, while the heavily-doped n type impurity diffusion region 40 has an n type impurity introduced therein at a higher concentration than the offset region 38. The n type impurity thus introduced is activated by heat treatment. This heat treatment is conducted for 10 seconds at 950° C.

In the heavily-doped n type impurity diffusion region 40, the n type impurity reaches the silicon-germanium layer 22 lying below the strained silicon layer 23 (lightly-doped n type impurity diffusion region 32) but the amount of the n type impurity introduced into the silicon-germanium layer 22 is much smaller than the amount introduced into the strained silicon layer 35 or strained silicon layer 23 (lightly-doped n type impurity diffusion region 32) so that, as seen in the drawing, the heavily-doped n type impurity diffusion region 40 seems to be formed in the strained silicon layer 35 and strained silicon layer 23 (lightly-doped n type impurity diffusion region 32).

As illustrated in FIG. 3, a silicon oxide film 41, which will serve as an interlayer insulating film, is formed over the main surface of the semiconductor substrate 20. The silicon oxide film 41 can be formed using, for example, CVD. The silicon oxide film 37 formed in FIG. 21 is made of a similar material to that of the silicon oxide film 41 which will be an interlayer insulating film so that it is omitted from FIG. 3.

By using photolithography and etching, a contact hole 42 is formed in the silicon oxide film 41. Over the silicon oxide film 41, including the bottom surface and inside wall of the contact hole 42 thus formed, a titanium/titanium nitride film 43a is formed. The titanium/titanium nitride film 43a is made of a film stack consisting of a titanium film and titanium nitride film, and it can be formed, for example, by sputtering. This titanium/titanium nitride film 43a prevents diffusion of tungsten, which is a material of a film to be filled in a later step, into silicon. In short, it has a barrier property.

A tungsten film 43b is then formed all over the main surface of the semiconductor substrate 20 so as to fill the contact hole 42. This tungsten film 43b can be formed, for example, by using CVD. By removing unnecessary portions of the titanium/titanium nitride film 43a and tungsten film 43b formed over the silicon oxide film 41, for example, by CMP, a plug 44 can be formed.

Over the silicon oxide film 41 and plug 44, a titanium/titanium nitride film 45a, aluminum film 45b and titanium/titanium nitride film 45c are successively formed. These films can be formed using, for example, sputtering. These films are then patterned using photolithography and etching to form an interconnection 46. Another interconnection is formed over the interconnection 46, but a description on it is omitted here.

According to Embodiment 1, large portions of the lightly-doped n type impurity diffusion region 32, offset region 38 and heavily-doped n type impurity diffusion region 40 constituting the drain region are formed in the strained silicon layer 23 and strained silicon layer 35, each having a high electron mobility, so that a drastic reduction in the sheet resistance can be attained by this improvement in electron mobility. A reduction in the sheet resistance leads to a reduction in the on-resistance of the power MISFETQ₁. As a result, a power amplifier having this power MISFETQ₁ mounted thereon has an improved efficiency.

As described above, the appearance of defects in the strained silicon layer 35 is influenced by the size of the growth region. It is also influenced by the heat treatment step conducted after the growth of the strained silicon layer 35. More specifically, as the temperature of the heat treatment conducted after the growth of the strained silicon layer 35 is higher and heat treatment time is longer, the strained silicon layer 35 has a higher probability of defect generation.

In Embodiment 1, the strained silicon layer 35 is formed utilizing epitaxial growth, and its formation is conducted after the steps of forming the element isolating trench 24, forming the p well 26, and forming the gate electrode 30. The strained silicon layer 35 is therefore free from the influence of heat treatment conducted in each of the steps of forming the element isolating trench 24, forming the p well 26, and forming the gate electrode 30. According to Embodiment 1, the probability of defect generation in the strained silicon layer 35 can be reduced further. In addition, the strained silicon layer 35 can be formed using the gate electrode 30 as a mask, because the strained silicon layer 35 is formed after the formation of the gate electrode 30.

### Embodiment 2

In Embodiment 1, an example in which the strained silicon layer 35 is formed after the formation of the lightly-doped n type impurity diffusion region 32 has been described. In Embodiment 2, on the other hand, a method in which the lightly-doped n type impurity diffusion region 32 is formed after the formation of the strained silicon layer 35 will be described.

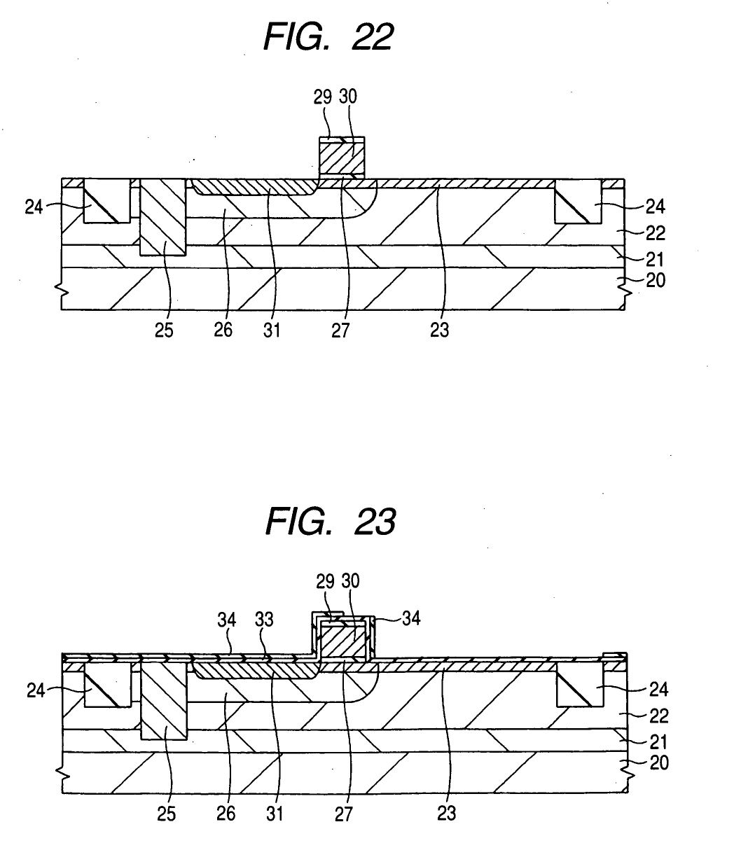

Steps from FIGS. 8 to 12 are adapted similar to those in Embodiment 1. As illustrated in FIG. 22, the exposed gate insulating film 27 is then removed from the main surface of the semiconductor substrate 20. After successive formation of a silicon oxide film 33 and a silicon nitride film 34 over the main surface of the semiconductor substrate 20, the silicon nitride film 34 is patterned as illustrated in FIG. 23 by using photolithography and anisotropic dry etching. The patterning is conducted so as to remove the silicon nitride film 34 over the drain formation region, while leaving the silicon nitride film 34 over the side walls of the gate electrode 30.

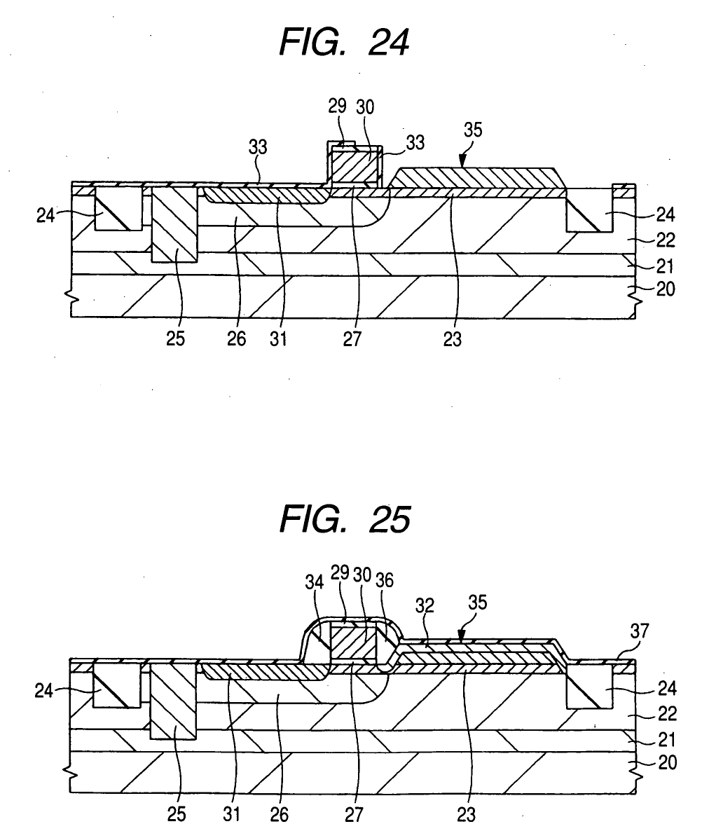

Using the patterned silicon nitride film 34 as a mask, the silicon oxide film 33 over the drain formation region is removed by wet etching to expose the strained silicon layer 23 over the drain formation region. After removal of the patterned silicon nitride film 34, a strained silicon layer 35 of about 40 nm in thickness is formed selectively over the strained silicon layer 23 exposed over the drain formation region, as illustrated in FIG. 24. The strained silicon layer 35 can be formed, for example, by selective epitaxial growth.

As illustrated in FIG. 25, a lightly-doped n type impurity diffusion region 32 extending over the strained silicon layer 23 and strained silicon layer 35 is formed utilizing photolithography and ion implantation. The lightly-doped n type impurity diffusion region 32 is formed by introducing an n type impurity into the strained silicon layer 23 and strained silicon layer 35. The impurity thus introduced is then activated by heat treatment.

In Embodiment 1, after the formation of the lightly-doped n type impurity diffusion region 32 in the strained silicon layer 23, the strained silicon layer 35 is formed over the lightly-doped n type impurity diffusion region 32, as illustrated in FIG. 18. In Embodiment 2, on the other hand, after the formation of the strained silicon layer 35 over the strained silicon layer 23 by using epitaxial growth, the lightly-doped n type impurity diffusion region 32 is formed. In Embodiment 2, since the underlying strained silicon layer 23 has a lower impurity concentration upon selective growth of the strained silicon layer 35 compared with that in Embodiment 1, it is possible to form the strained silicon layer 35, which permits easy cleaning of the underlying film and has fewer defects. More specifically, the surface of the strained silicon layer 23 is washed prior to the selective growth of the strained silicon layer 35 over the strained silicon layer 23. When an impurity is introduced in a larger amount into the underlying strained silicon layer 23, oxygen atoms or carbon atoms tend to attach thereto upon washing. When the strained silicon layer 35 is caused to grow without removing such foreign matter from the underlying layer, defects tend to occur. In this Embodiment 2, in which the lightly-doped n type impurity diffusion region 32 is formed after the formation of the strained silicon layer 35, generation of defects can be suppressed compared with Embodiment 1, in which the strained silicon layer 35 is formed after formation of the lightly-doped n type impurity diffusion region 32.

As illustrated in FIG. 25, after the formation of a silicon oxide film over the main surface of the semiconductor substrate 20, the resulting silicon oxide film is subjected to anisotropic dry etching, whereby side walls 36 are formed over the side surfaces of the gate electrode 30. A silicon oxide film 37 is then formed over the main surface of the semiconductor substrate 20.

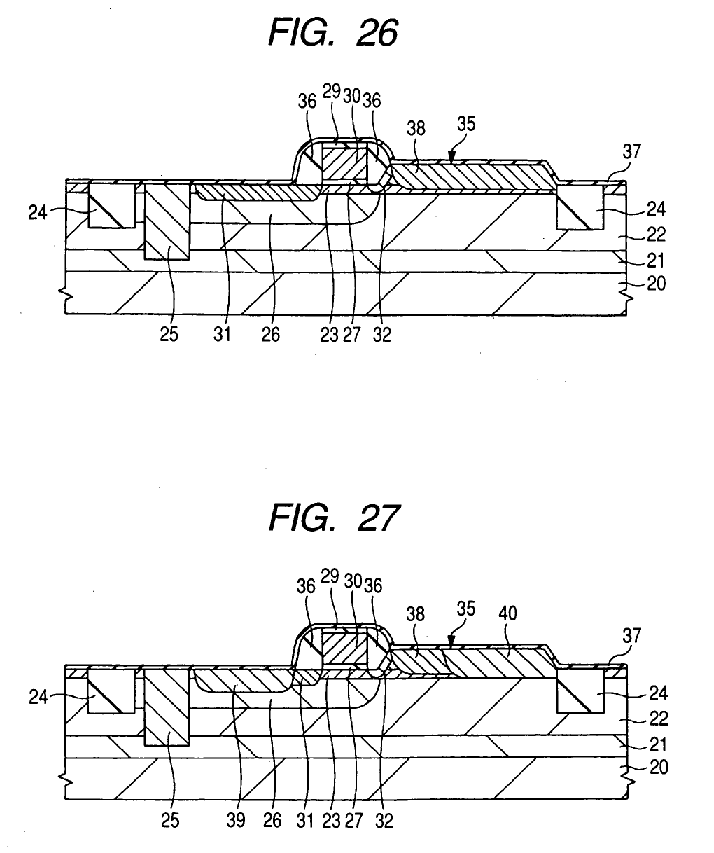

As illustrated in FIG. 26, an offset region 38 is formed using photolithography and ion implantation. Most of the offset region 38 is formed in the strained silicon layer 23 and strained silicon layer 35. The concentration of an impurity introduced into the offset region is higher than that in the lightly-doped n type impurity diffusion region 32. The n type impurity thus introduced is then activated by heat treatment.

As illustrated in FIG. 27, a heavily-doped n type impurity diffusion region 39, which will constitute a part of the source region, is formed outside of the n type impurity diffusion region 31 and a heavily-doped n type impurity diffusion region 40, which will constitute a part of the drain region, is formed outside the offset region 38, by using photolithography and ion implantation. At this time, most of the heavily-doped n type impurity diffusion region 40 is formed in the strained silicon layer 23 and strained silicon layer 35.

An n type impurity is introduced at a higher concentration in the heavily-doped n type impurity diffusion region 39 than in the n type impurity diffusion region 31, while an n type impurity is introduced at a higher concentration in the heavily-doped n type impurity diffusion region 40 than in the offset region 38. The n type impurity introduced in the heavily-doped n type impurity diffusion region 39 and 40 are activated by heat treatment.

By subsequent steps similar to those employed in Embodiment 1, a plug 44 and an interconnection 46 are formed, as illustrated in FIG. 3. In such a manner, the power MISFETQ₁ having similar effects to that of Embodiment 1 can be formed.

### Embodiment 3

In Embodiment 1, an example in which side walls 36 are formed over the side surfaces of the gate electrode 30 was described. In Embodiment 3, an example in which side walls 36 are not formed over the side surfaces of the gate electrode 30 will be described.

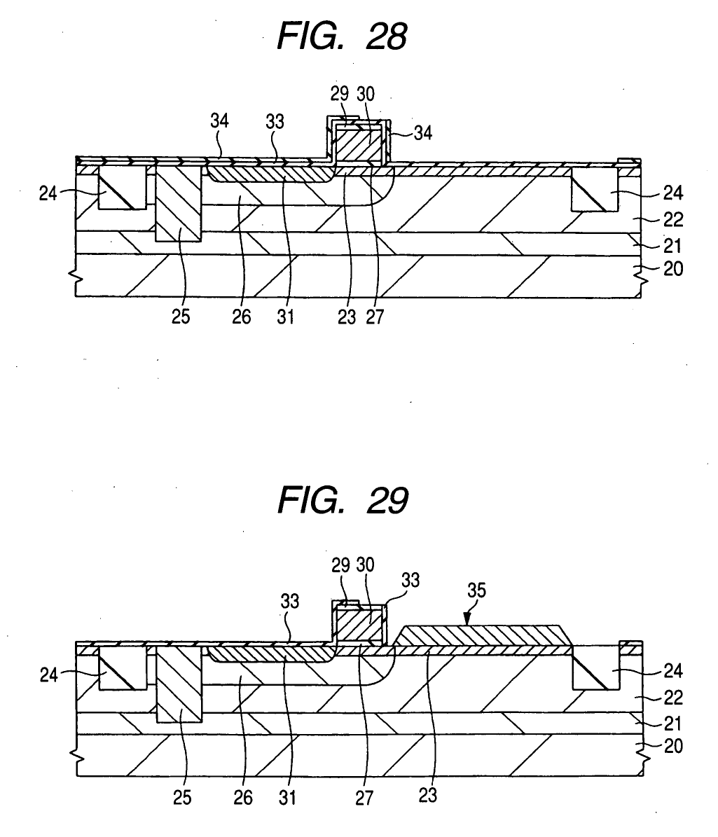

Steps from FIG. 8 to FIG. 12 are adopted similar to those of Embodiment 1. The gate insulating film 27 exposed over the main surface of the semiconductor substrate 20 is then removed. After successive formation of a silicon oxide film 33 and a silicon nitride film 34 over the main surface of the semiconductor substrate 20, the silicon nitride film 34 is patterned, as illustrated in FIG. 28, by using photolithography and anisotropic dry etching. This patterning is conducted to remove the silicon nitride film 34 over the drain formation region, while leaving the silicon nitride film 34 over the side walls of the gate electrode 30.

Using the patterned silicon nitride film 34 as a mask, the silicon oxide film 33 over the drain formation region is removed by wet etching to expose the strained silicon layer 23 over the drain formation region. After removal of the patterned silicon nitride film 34, a strained silicon layer 35 of about 40 nm in thickness is formed selectively over the strained silicon layer 23 exposed over the drain formation region, as illustrated in FIG. 29. This strained silicon layer 35 can be formed, for example, by selective epitaxial growth.

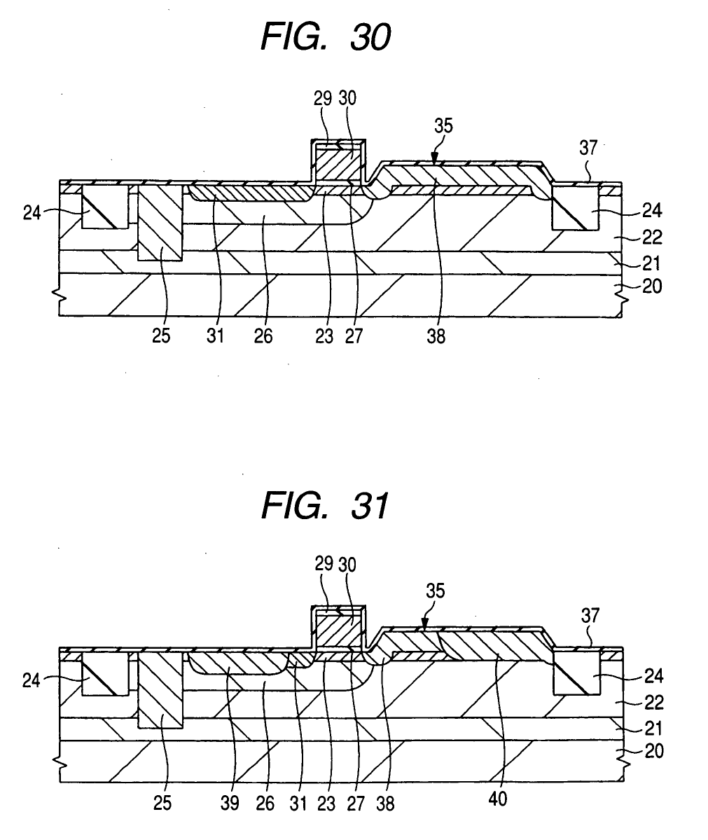

As illustrated in FIG. 30, after formation of a silicon oxide film 37 over the main surface of the semiconductor substrate 20, an offset region 38 is formed using photolithography and ion implantation. The offset region 38 is formed by the introduction of an n type impurity. At this time, a large portion of the offset region 38 is formed in the strained silicon layer 35. The impurity thus introduced is then activated by heat treatment.

As illustrated in FIG. 31, a heavily-doped n type impurity diffusion region 39, which will constitute a part of the source region, is formed outside of the n type impurity diffusion region 31, and a heavily-doped n type impurity diffusion region 40, which will constitute a part of the drain region, is formed outside the offset region 38, by using photolithography and ion implantation. At this time, a large portion of the heavily-doped n type impurity diffusion region 40 is formed in the strained silicon layer 23 and strained silicon layer 35. The n type impurity introduced into each of the highly-doped n-type impurity diffusion regions 39 and 40 is activated by heat treatment.

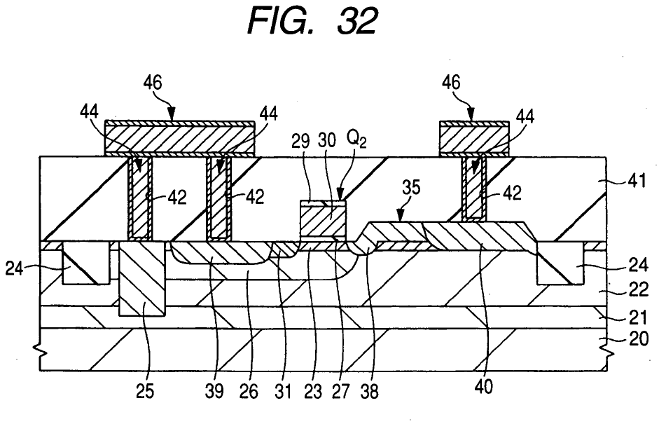

By subsequent steps similar to those of Embodiment 1, a plug 44 and an interconnection 46 are formed, as illustrated in FIG. 32. In such a manner, a power MISFETQ₂ having no side walls formed over the side surfaces of the gate electrode 30 can be formed.

In Embodiment 1, the lightly-doped drain region has a dual structure made of the lightly-doped n type impurity diffusion region 32 and offset region 38, while in this Embodiment 3, the lightly-doped drain region is composed of only the offset region 38. A step of forming the side walls 36 is therefore not necessary in this Embodiment, which enables simplification of the steps employed in the manufacture of the power MISFETQ₂, compared with those of Embodiment 1.

Similar to Embodiment 1, most of the offset region 38 and heavily-doped n type impurity diffusion region 40 can be formed in the strained silicon layer 23 and strained silicon layer 35, each having a high electron mobility, so that a drastic reduction in the sheet resistance can be attained owing to an improvement in the electron mobility. The reduction in the sheet resistance leads to a reduction in the on-resistance of the power MISFETQ₂. As a result, a power amplifier having this power MISFETQ₂ mounted thereon has an improved efficiency.

### Embodiment 4

In Embodiment 1, an example in which the strained silicon layer 35 is formed only over the drain formation region was described. In this Embodiment 4, on the other hand, an example in which a strained silicon layer 35 is formed over each of the drain formation region and source formation region will be described.

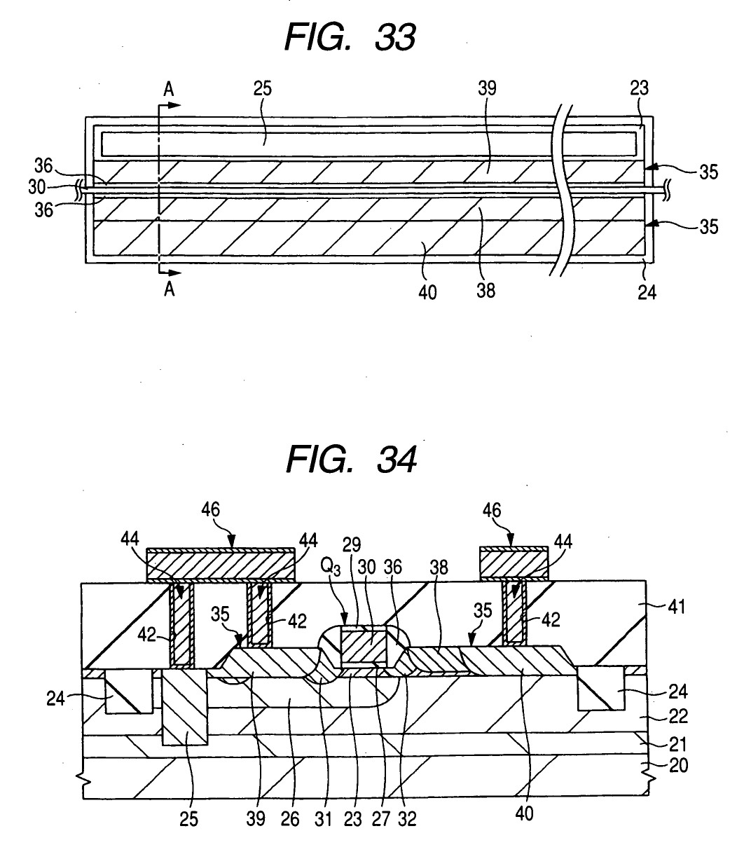

FIG. 33 is a plan view mainly illustrating a power MISFETQ₃ in Embodiment 4. FIG. 33 is almost similar to FIG. 2, which is a plan view of the power MISFETQ₁ of Embodiment 1, so that only the differences will be described.

What is different in FIG. 33 from FIG. 2 is that the strained silicon layer 35 is formed also over the source region. More specifically, the strained silicon layer 35 in FIG. 2 is formed only on one (drain region) of two sides, with the gate electrode 30 sandwiched therebetween, while in FIG. 33, the strained silicon layer 35 marked with diagonal lines is formed on both sides (source region and drain region), with the gate electrode sandwiched therebetween.

FIG. 34 is a cross-sectional view taken along a line A-A of FIG. 33. FIG. 34 is also substantially similar to FIG. 3, which is a cross-sectional view of the power MISFETQ₁ of Embodiment 1. What is different in FIG. 34 from FIG. 3 is that the strained silicon layer 35 is formed also over the source region, and most of the heavily-doped n type impurity diffusion region 39 is formed in the strained silicon layer 35 and the strained silicon layer 23 lying below the strained silicon layer 35.

A method of manufacture of the power MISFETQ₃ according to Embodiment 4 will be explained next with reference to the drawings.

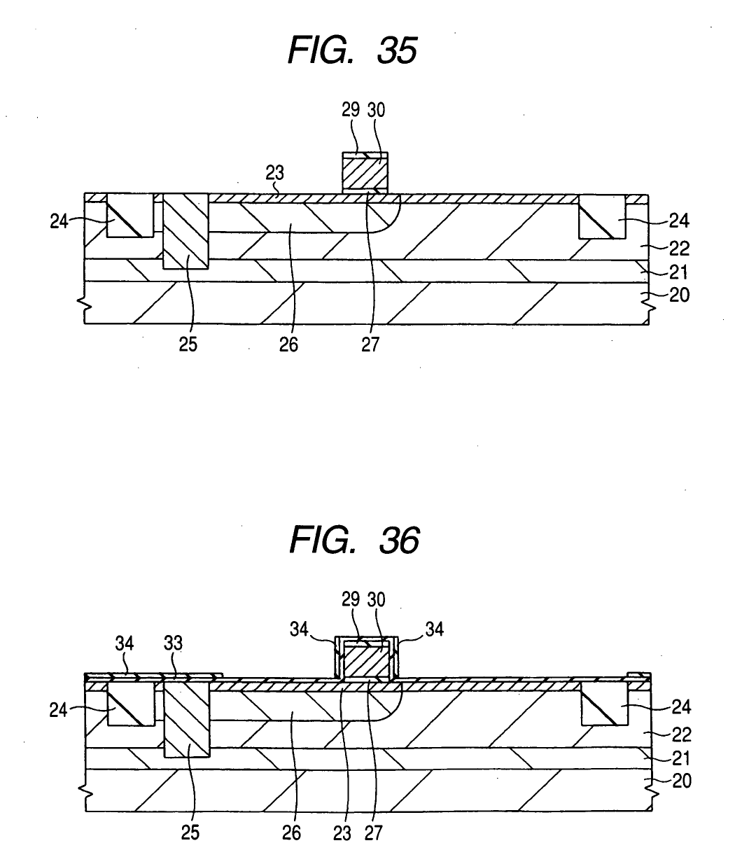

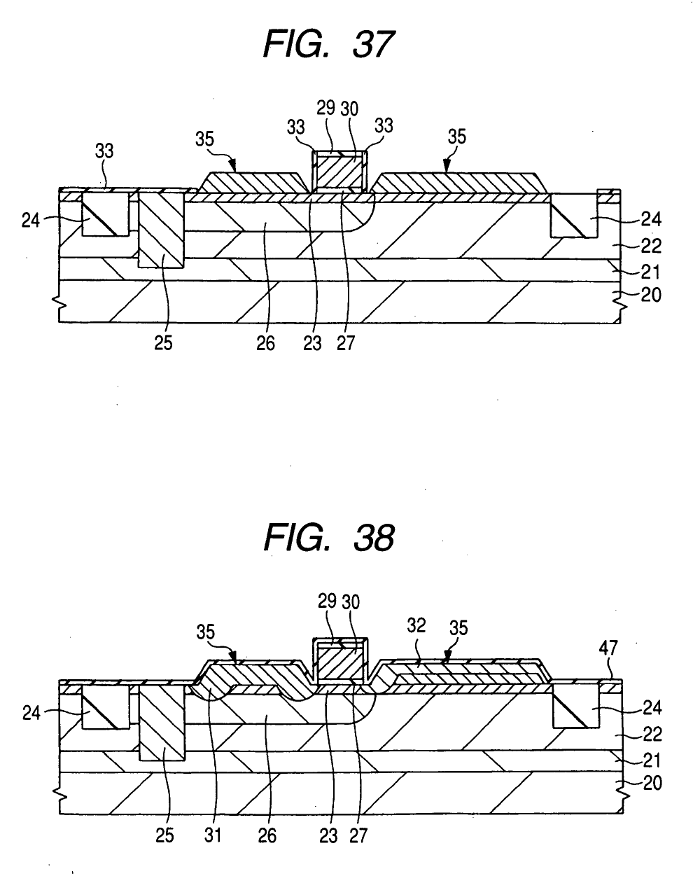

Steps from FIG. 8 to FIG. 11 are similar to those of Embodiment 1. Then, a gate electrode 30 is formed as illustrated in FIG. 35 by photolithography and etching, and, at the same time, the gate insulating film 27 exposed over the main surface of the semiconductor substrate 20 is removed.

After successive formation of a silicon oxide film 33 and a silicon nitride film 34 over the main surface of the semiconductor substrate 20, the silicon nitride film 34 is patterned, as illustrated in FIG. 36, by using photolithography and anisotropic dry etching. This patterning is carried out to remove the silicon nitride film 34 over the drain formation region and the source formation region, while leaving the silicon nitride film 34 over the side surfaces of the gate electrode 30.

Using the patterned silicon nitride film 34 as a mask, the silicon oxide film 33 over the drain formation region and source formation region is removed by wet etching, whereby the strained silicon layer 23 over the drain formation region and the source formation region is exposed. After removal of the patterned silicon nitride film 34, a strained silicon layer 35 of about 40 nm in thickness is formed selectively over the strained silicon layer 23 that is exposed over the drain formation region and the source formation region. This strained silicon layer 35 can be formed, for example, by selective epitaxial growth.

The patterning of the silicon nitride film 34 in Embodiment 4 is carried out to make openings for the drain formation region and source formation region. By this, the strained silicon layer 35 is formed in both the source formation region and drain formation region. The patterning of the silicon nitride film 34 in Embodiment 1 is, on the other hand, conducted to make an opening for only the drain formation region. As illustrated in FIG. 16, patterning is conducted so as to leave the silicon nitride film 34 on the side of the source formation region relative to the center of the gate electrode 30, while removing the silicon nitride film 34, except that over the side walls of the gate electrode 30, on the side of the drain formation region relative to the center of the gate electrode 30. In Embodiment 1, the silicon nitride film 34 must be patterned in alignment with the gate electrode 30, which requires a highly precise mask. This presumably makes the manufacturing step complicated.

In Embodiment 4, on the other hand, patterning of the silicon nitride film 34 is conducted to make openings on both sides of the gate electrode 30, and patterning of the silicon nitride film 34 in consideration of the width of the gate electrode is not necessary. The mask of Embodiment 4 is therefore not required to be as accurate as that of Embodiment 1, and this enables simplification of the manufacture of the power MISFETQ₃ of Embodiment 4.

As illustrated in FIG. 38, after formation of a silicon oxide film 47 over the main surface of the semiconductor substrate 20, an n type impurity diffusion region 31, which will constitute a part of the source region, and a lightly-doped n type impurity diffusion region 32, which will constitute a part of the drain region, are formed using photolithography and ion implantation. The n type impurity diffusion region 31 and lightly-doped n type impurity diffusion region 32 are formed by the introduction of an n type impurity. At this time, large portions of the n type impurity diffusion region 31 and lightly-doped n type impurity diffusion region 32 are formed in the strained silicon layer 23 and strained silicon layer 35. The impurity thus introduced is then activated by heat treatment.

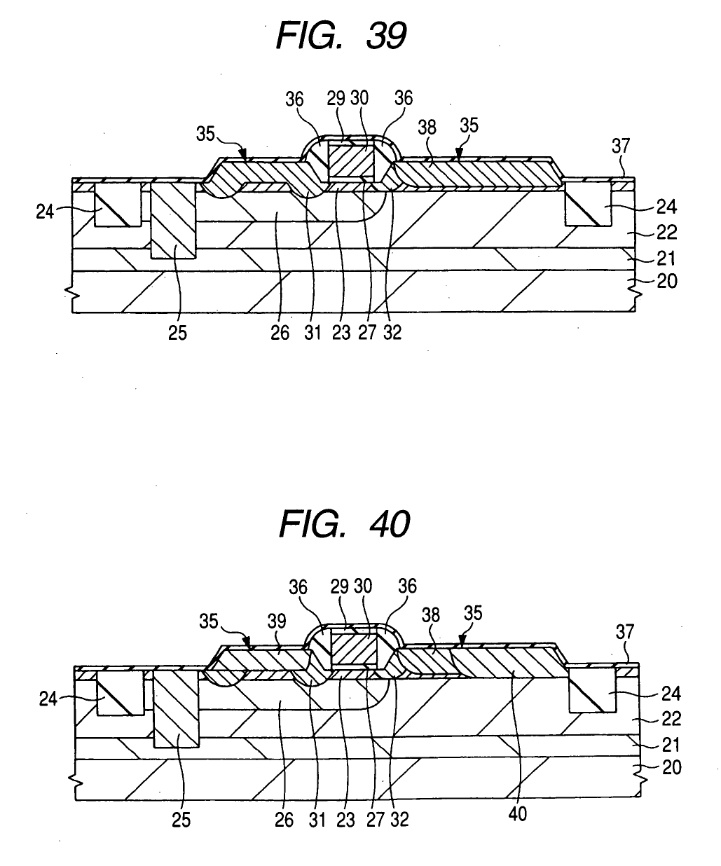

As illustrated in FIG. 39, after formation of a silicon oxide film over the main surface of the semiconductor substrate 20, the silicon oxide film is subjected to anisotropic dry etching to form side walls 36 over the side surfaces of the gate electrode 30. A silicon oxide film 37 is then formed over the main surface of the semiconductor substrate 20.

By using photolithography and ion implantation, an offset region 38 is formed outside of the lightly-doped n type impurity diffusion region 32. A large portion of the offset region 38 is formed in the strained silicon layer 23 and strained silicon layer 35. The n type impurity thus introduced in the offset region 38 is activated by heat treatment.

As illustrated in FIG. 40, a heavily-doped n type impurity diffusion region 39, which will constitute a part of the source region, is formed outside of the n type impurity diffusion region 31, and a heavily-doped n type impurity diffusion region 40, which will constitute a part of the drain region, is formed outside the offset region 38, by using photolithography and ion implantation. At this time, large portions of the heavily-doped n type impurity diffusion regions 39 and 40 are formed in the strained silicon layer 23 and strained silicon layer 35. The n type impurity introduced into each of the heavily-doped p type impurity diffusion regions 39 and 40 is activated by heat treatment.

By subsequent steps similar to those of Embodiment 1, plug 44 and an interconnection 46 are formed, as illustrated in FIG. 34. In such a manner, a power MISFETQ₃ having the strained silicon layer 35, which is caused to grow in both the source region and drain region can be formed.

Similar to Embodiment 1, large portions of the offset region 38 and heavily-doped n type impurity diffusion region 40 can be formed in the strained silicon layer 23 and strained silicon layer 35 having a high electron mobility so that a drastic reduction in the sheet resistance can be attained owing to an improvement in the electron mobility. The reduction in the sheet resistance leads to a reduction in the on-resistance of the power MISFETQ₃. As a result, a power amplifier having this power MISFETQ₃ mounted thereon has an improved efficiency.

### Embodiment 5

In Embodiment 1, an example in which the strained silicon layer 35 is formed over almost the whole region of the drain formation region was described. In Embodiment 5, on the other hand, an example in which the strained silicon layer 35 is formed over a portion of the drain formation region will be described.

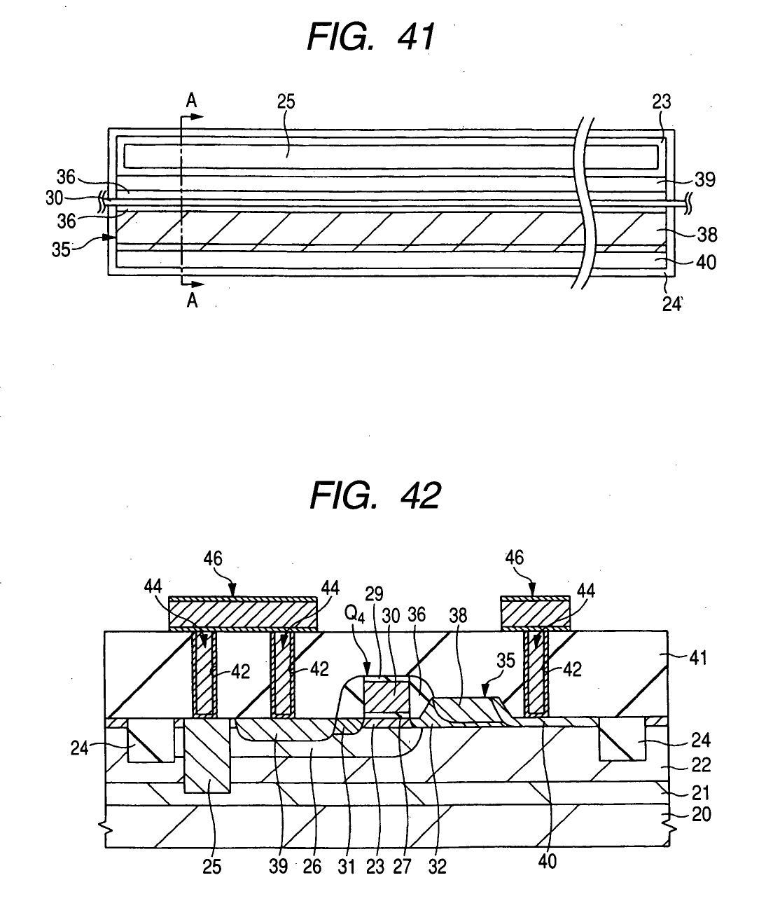

FIG. 41 is a plan view mainly illustrating the power MISFETQ₄ according to Embodiment 5. FIG. 41 is almost similar to FIG. 2, which is a plan view of the power MISFETQ₁ according to Embodiment 1, so that only the difference between them will be explained.

What is different in FIG. 41 from FIG. 2 is that the strained silicon layer 35 is formed only over a portion of the drain region. More specifically, in FIG. 2, the strained silicon layer 35 is formed over almost the whole region on one (drain region) of two sides, with the gate electrode 30 sandwiched therebetween, while in FIG. 41, the strained silicon layer 35 marked with diagonal lines is formed over a portion of the drain region. In short, the difference from Embodiment 1 resides in the formation of the strained silicon layer 35 mainly in the offset region 38 of the drain region.

FIG. 42 is a cross-sectional view taken along a line A-A of FIG. 41. FIG. 42 is almost similar to FIG. 3, which is a cross-sectional view of the power MISFETQ₁ according to Embodiment 1. What is different in FIG. 42 from FIG. 3 is that the strained silicon layer 35 is formed only and mainly in the lightly-doped drain region (lightly-doped n type impurity diffusion region 32 and offset region 38) of the drain region. In Embodiment 5, large portions of the lightly-doped n type impurity diffusion region 32 and offset region 38 are formed in the strained silicon layer 35.

A method of manufacture of the power MISFETQ₄ according to Embodiment 5 will be explained next with reference to the accompanying drawings.

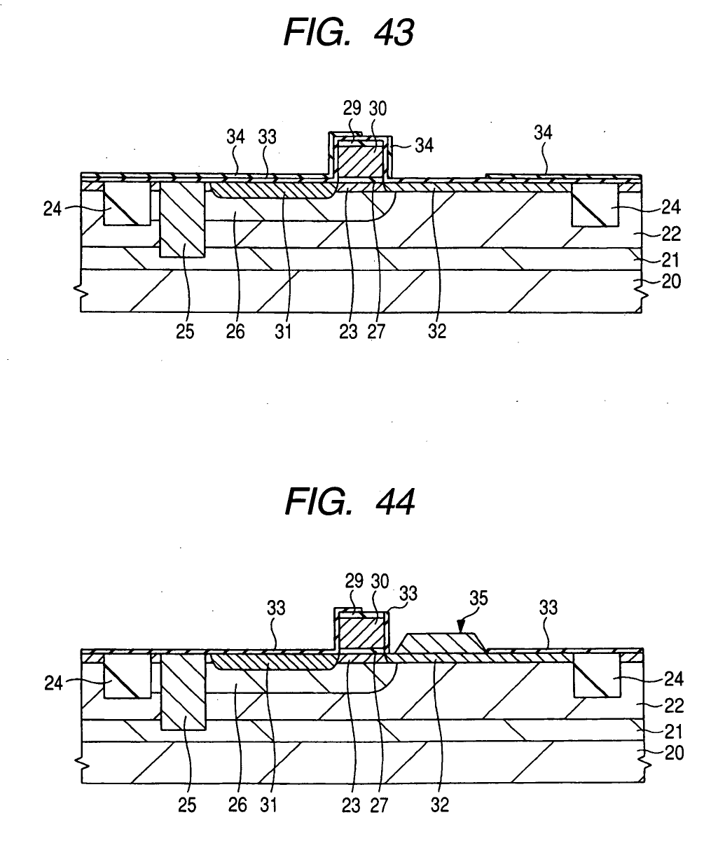

Steps from FIG. 8 to FIG. 15 are similar to those in Embodiment 1. The silicon nitride film 34 is then patterned, as illustrated in FIG. 43, by photolithography and etching. The patterning is conducted so as to remove the silicon nitride film 34 over a portion of the drain formation region, while leaving the silicon nitride film 34 on the side surfaces of the gate electrode 30. In other words, an opening is made over a portion (a region which will be a lightly-doped drain region) of the drain formation region near the gate electrode 30, while an opening is not made over a portion (which will be a heavily-doped drain region) of the drain formation region apart from the gate electrode 30.

Using the patterned silicon nitride film 34 as a mask, the silicon oxide film 33 over a portion of the drain formation region is removed by wet etching to expose the strained silicon layer 23 (lightly-doped n type impurity diffusion region 32) over a portion of the drain formation region. After removal of the patterned silicon nitride film 34, a strained silicon layer 35 of about 40 nm in thickness is selectively formed over the strained silicon layer 23 (lightly-doped n type impurity diffusion region 32) exposed over a portion of the drain formation region, as illustrated in FIG. 44. This strained silicon layer 35 can be formed, for example, by selective epitaxial growth.

In Embodiment 5, the strained silicon layer 35 is caused to grow, not over almost the whole region, of the drain formation region but only over a portion (a region to be a lightly-doped drain region) of the drain formation region, while the strained silicon layer 35 is not caused to grow in a region which will be a heavily-doped drain region. Compared with Embodiment 1, in which the strained silicon layer 35 is formed over almost the whole drain formation region, the growth region of the strained silicon layer 35 is narrow. By narrowing the growth region of the strained silicon layer 35, the strained silicon layer 35 with fewer defects can be formed. In Embodiment 5, narrowing of the growth region of the strained silicon layer 35 facilitates stress relaxation in the strained silicon layer 35, whereby the strained silicon layer 35 with fewer defects can be formed. Embodiment 5 therefore attains a reduction in the leakage current due to defects.

Subsequent steps are similar to those of Embodiment 1, as illustrated in FIGS. 19 to 21. Finally, the MISFETQ₄ having the strained silicon layer 35 formed only in the lightly-doped drain region can be formed as illustrated in FIG. 42.

Embodiment 5 makes it possible to form a large portion of the offset region 38 in the strained silicon layer 23 and strained silicon layer 35, each having a high electron mobility, so that a drastic reduction in the sheet resistance owing to improvement in the electron mobility can be attained. This reduction in sheet resistance leads to a reduction in the on-resistance of the power MISFETQ₄. As a result, a power amplifier having this power MISFETQ₄ mounted thereon has an improved efficiency. (Embodiment 6).

In Embodiment 5, an example in which the strained silicon layer 35 is formed only over a portion of the drain formation region was described. In Embodiment 6, on the other hand, an example in which the strained silicon layer 35 is formed in a narrower region will be described.

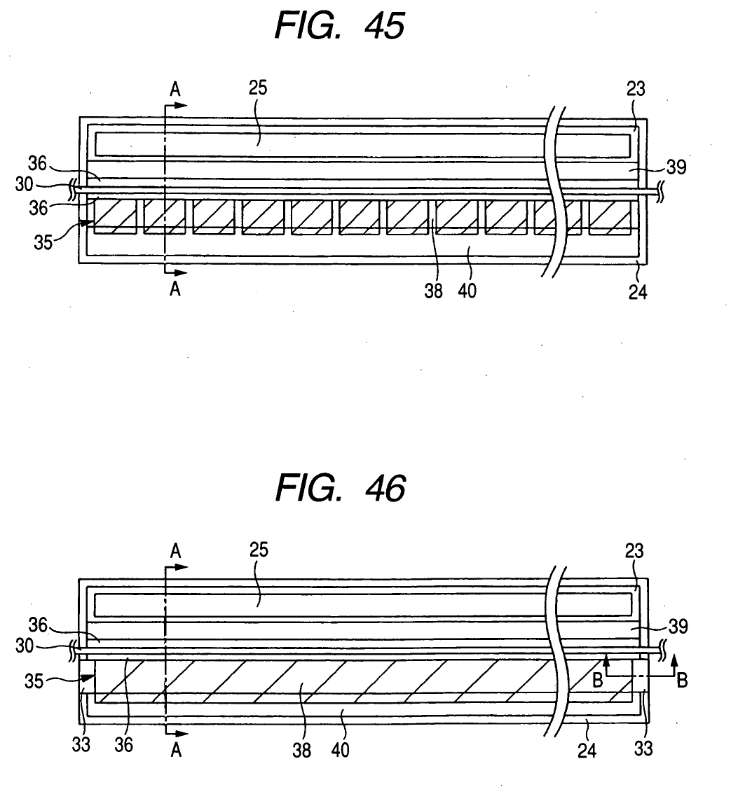

FIG. 45 is a plan view mainly illustrating a power MISFET according to Embodiment 6. FIG. 45 is almost similar to FIG. 41, which is a plan view of the power MISFETQ₄ according to Embodiment 5, so that only the difference between them will be described next.

What is different in FIG. 45 from FIG. 41 is that the strained silicon layer 35 is formed only over a portion of the drain region, and the strained silicon layer 35 is divided into several sections in an extending direction of the gate electrode 30. More specifically, in FIG. 41, the strained silicon layer 35 is formed as one continuous layer mainly and only over the offset region 38 of the drain region; while, in FIG. 45, the strained silicon layer 35 is formed mainly over the offset region 38, and, at the same time, it is divided into plural sections in the extending direction of the gate electrode 30.

Division of the formation region of the strained silicon layer 35 into plural sections makes it possible to further decrease the number of defects generated in the strained silicon layer 35, compared with that of Embodiment 5. Since the strained silicon layer 35 is divided into plural sections in the extending direction of the gate electrode 30, each of these sections of the strained silicon layer 35 is narrow, and the stress in the strained silicon layer 35 can be relaxed. This leads to a further reduction in the probability of defect generation and, in addition, to a reduction in the leakage current which will otherwise occur owing to defect generation.

The cross-section taken along a line A-A of FIG. 45 is similar to FIG. 42 of Embodiment 5. According to Embodiment 6, as in Embodiment 5, a large portion of the offset region 38 can be formed in the strained silicon layer 23 and strained silicon layer 35, each having a high electron mobility, so that a drastic reduction in the sheet resistance due to improvement in the electron mobility can be attained.

A method of manufacture of the power MISFET according to Embodiment 6 is almost similar to that according to Embodiment S. In Embodiment 6, in contrast to Embodiment 5, however, a region in which the strained silicon layer 35 is caused to grow selectively over the strained silicon layer 23 (lightly-doped n type impurity diffusion region 32) is different, which is brought about by a change in patterns formed by photolithography. In Embodiment 6, patterning is carried out so as to divide the region, from which the strained silicon layer 23 (lightly-doped n type impurity diffusion region 32) is exposed to cause the growth of the strained silicon layer 35, into a plurality of sections in the extending direction of the gate electrode 30.

### Embodiment 7

In Embodiment 7, an example of forming the strained silicon layer 35 apart from the element isolation region 24, which serves to provide a separation between elements, will be explained.

FIG. 46 is a plan view mainly illustrating the power MISFET of Embodiment 6. FIG. 46 is almost similar to FIG. 41, which is a plan view of the power MISFETQ₄ of Embodiment 5, so that only the difference between them will be explained.

The difference between FIG. 46 and FIG. 41 resides in the fact that end portions of the strained silicon layer 35 marked with diagonal lines are not in direct contact with the element isolation region 24 in the extending direction of the gate electrode 30. More specifically, in the structure of FIG. 46, a silicon oxide film 33 is formed between the element isolation region 24 and the strained silicon layer 35, and the growth of the strained silicon layer 35 from its site in contact with the element isolation region 24 is suppressed. In other words, the strained silicon layer 35 is, at both end portions thereof in the extending direction of the gate electrode 30, not brought into direct contact with the element isolation region 24.

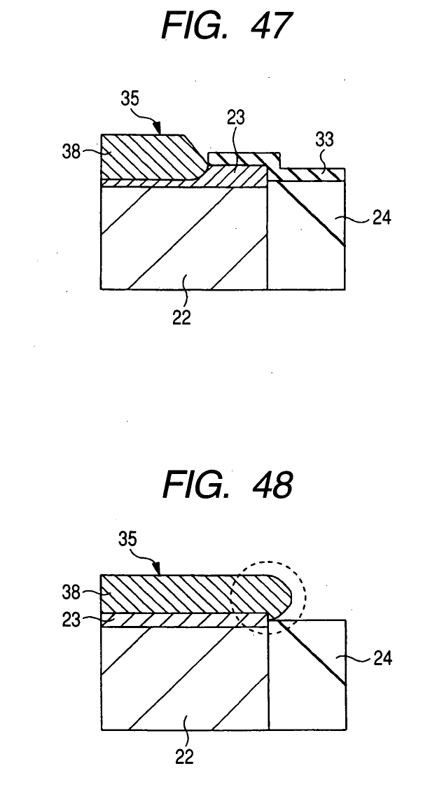

Such a structure is adopted for the following reasons. FIG. 47 is a cross-sectional view taken along a line B-B of FIG. 46. As illustrated in FIG. 47, a step difference exists between the strained silicon layer 23 and the element isolation region 24. This appears because, after the formation of the element isolation region 24, etching for the removal of the silicon oxide film formed over the main surface of the semiconductor substrate 20 also removes the surface of the element isolation region 24, which is made of a material similar to the silicon oxide film. As illustrated in FIG. 48, when the strained silicon layer 35 is caused to grow in the vicinity of the boundary between the strained silicon layer 23 and the element isolation region 24 without removing a step difference, the strained silicon layer 35 is formed to cover the step difference at the boundary between the strained silicon layer 23 and the element isolation region 24. When the strained silicon layer 35 grows so as to cover this step difference, defects tend to occur owing to internal stress. In Embodiment 7, in order to suppress the generation of such defects, the silicon oxide film 33 is formed between the strained silicon layer 23 and element isolation region 24, as illustrated in FIG. 47, whereby the formation of the strained silicon layer 35 from the step difference portion is prevented. In Embodiment 7, therefore, the strained silicon layer 35 with fewer defects can be formed, and generation of a leakage current, which will otherwise occur due to defects, can be reduced.

A cross-sectional view taken along a line A-A of FIG. 46 is similar to FIG. 42 of Embodiment 5. Accordingly in Embodiment 7, as in Embodiment 5, a large portion of the offset region 38 can be formed in the strained silicon layer 23 and strained silicon layer 35 having a high electron mobility, so that a drastic reduction in the sheet resistance can be attained by this improvement in the electron mobility.

A method of manufacture of the power MISFET according to Embodiment 7 is almost similar to that of Embodiment 5. In Embodiment 7, in contrast to different from Embodiment 5, however, a selective growth region of the strained silicon layer 35 over the strained silicon layer 23 (lightly-doped n type impurity diffusion region 32) is different, which is brought by a change in patterns formed by photolithography. More specifically, as illustrated in FIG. 47, the silicon oxide film 33 is formed over the strained silicon layer 23 and element isolation region 24, followed by patterning of the silicon oxide film 33 so as to leave-of a region of the strained silicon layer 23 on the drain region side-the silicon oxide film 33 formed over the vicinity of a region in contact with the element isolation region 24 and to remove the silicon oxide film 33 formed over a portion of the drain formation region. The silicon oxide film 33 is then removed, and, in a region from which the strained silicon layer 23 is exposed by this removal, the strained silicon layer 35 is caused to grow selectively. Subsequent steps similar to those of Embodiment 5 are executed, whereby a power MISFET in which the strained silicon layer 35 is not in contact with the element isolation region 24 for providing a separation between elements can be formed.

Similar to Embodiment 5, the strained silicon layer 35 grows in the lightly-doped drain region (mainly, offset region 38) in Embodiment 7. Accordingly, the strained silicon layer 35 is not formed at the end portions of the lightly-doped drain region which is in contact with the element isolation region 24.

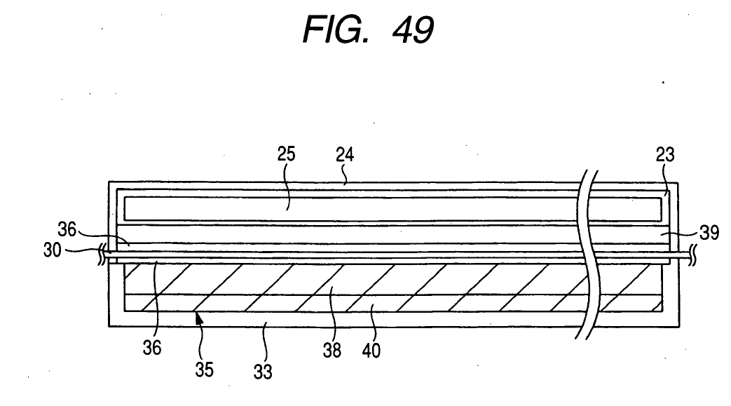

As described above, the selective growth region for the strained silicon layer 35 in Embodiment 7 is a region which will be the lightly-doped drain region (mainly, offset region 38). This Embodiment 7 can also be applied, for example, to the structure illustrated in FIG. 49 in which the selective growth region for the strained silicon layer 35 is not limited to a region which will be the lightly-doped drain region, but will also be a region which will be the heavily-doped drain region (heavily-doped n type impurity diffusion region 40). In this case, as illustrated in FIG. 49, the silicon oxide film 33 is formed even at the end portions of the heavily-doped drain region which is in contact with the element isolation region 24 so that it disturbs direct contact between the end portions of the heavily-doped drain region and the element isolation region 24. In other words, the strained silicon layer 35 is not formed at the end portions of the heavily-doped drain region which is in contact with the element isolation region 24.

### Embodiment 8

In Embodiment 8, a method of causing the growth of the strained silicon layer 35 after formation of the source region and the drain region will be described.

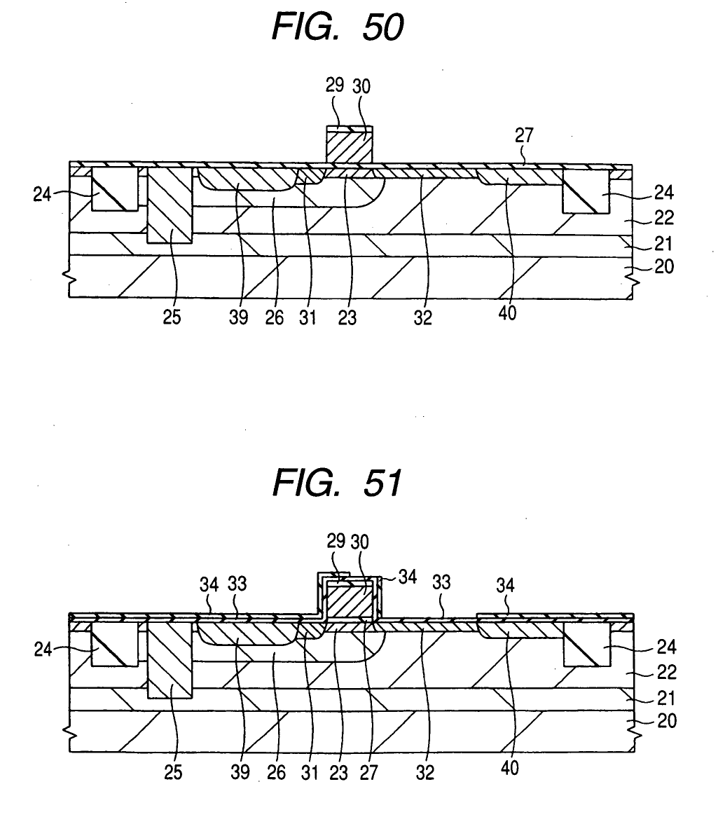

Steps from FIG. 8 to FIG. 13 are similar to Embodiment 1. As illustrated in FIG. 50, a heavily-doped n-type impurity diffusion region 39, which will constitute a portion of the source region, and a heavily-doped n type impurity diffusion region 40, which will constitute a portion of the drain region, are then formed by photolithography and ion implantation. An n type impurity is introduced into the heavily-doped n-type impurity diffusion regions 39 and 40, and it is activated by heat treatment.

After successive formation of a silicon oxide film 33 and a silicon nitride film 34 over the main surface of the semiconductor substrate 20, the silicon nitride film 34 is patterned as illustrated in FIG. 51 by using photolithography and anisotropic dry etching. The patterning is carried out so as to remove the silicon nitride film 34 formed over a portion of the drain formation region, which will be the lightly-doped drain region, while leaving the silicon nitride film 34 over the side surfaces of the gate electrode 30.

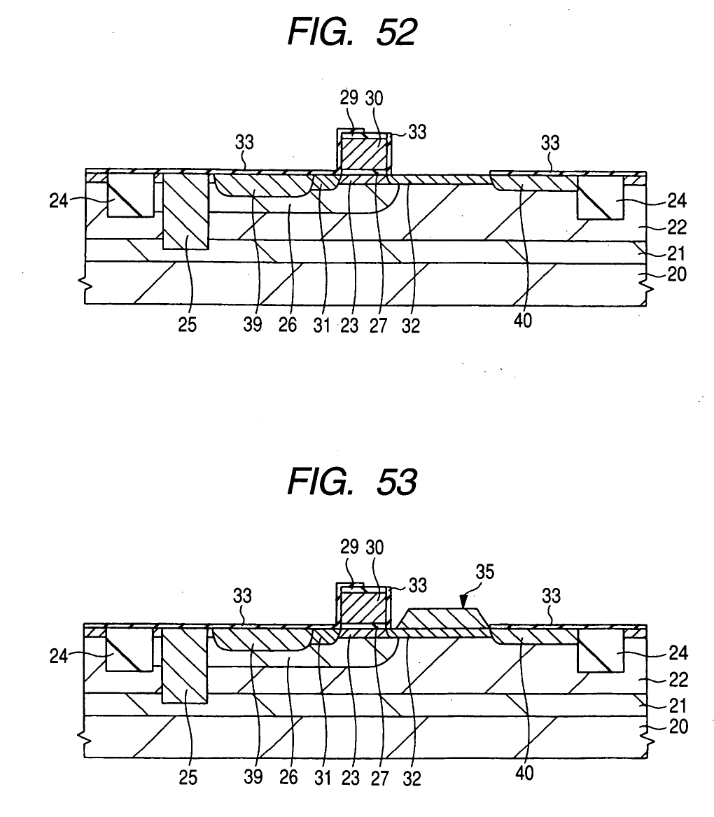

Using the patterned silicon nitride film 34 as a mask, the silicon oxide film 33 in a region which will be the lightly-doped drain region is removed by wet etching to expose the strained silicon layer 23 in a region which will be the lightly-doped drain region. After removal of the patterned silicon nitride film 34, as illustrated in FIG. 52, a strained silicon layer 35 doped with phosphorus as an n type impurity at a dosage of about 1.0×10¹⁸ cm⁻³ is formed, as illustrated in FIG. 53, to a thickness of about 40 nm over the strained silicon layer 23 exposed from a region which will be the lightly-doped drain region. The strained silicon layer 35 can be formed, for example, by selective epitaxial growth at a temperature adjusted to about 700° C.

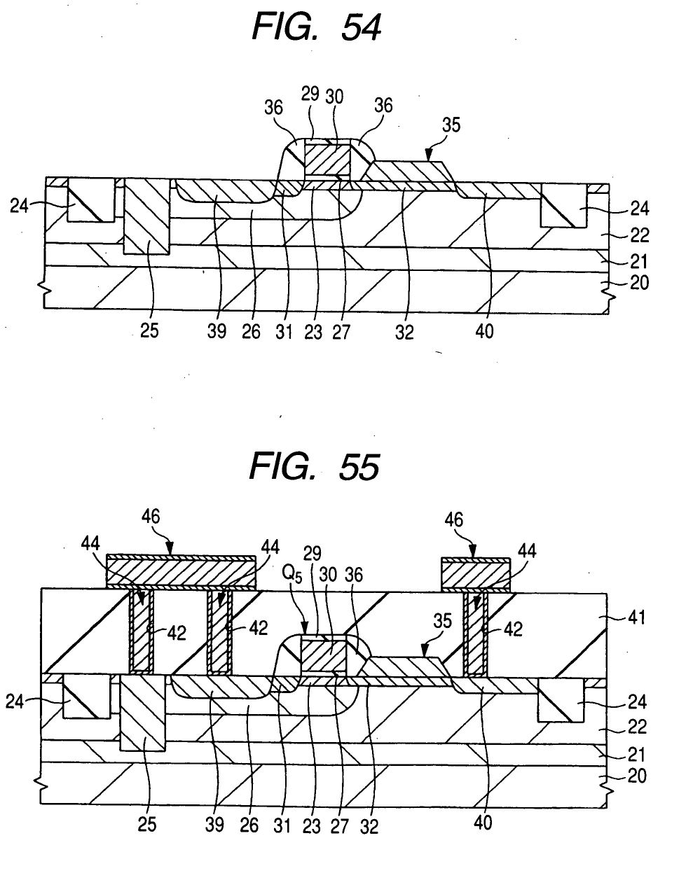

As illustrated in FIG. 54, after formation of a silicon oxide film over the main surface of the semiconductor substrate 20, side walls 36 are formed over the side surfaces of the gate electrode 30 by anisotropic dry etching.

By subsequent steps similar to those of Embodiment 1, a plug 44 and interconnection 46 are formed, as illustrated in FIG. 55, whereby a power MISFETQ₅ can be fabricated.

According to Embodiment 8, after the formation of the n type impurity diffusion region 31 and heavily-doped n-type impurity diffusion region 39, which will constitute the source region, and the lightly-doped n type impurity diffusion region 32 and heavily-doped n type impurity diffusion region 40, which will constitute the drain region, the strained silicon layer 35, which will be the offset region, is caused to grow over the strained silicon layer 23 (lightly-doped n type impurity diffusion region 32). The strained silicon layer 35 grows after completion of a thermal treatment higher than about 700° C. for the formation of these impurity diffusion regions, so that generation of defects which will otherwise appear in the strained silicon layer 35 can be suppressed in Embodiment 8.

Since the strained silicon layer 35 having a high electron mobility is caused to grow over the lightly-doped drain region, a drastic reduction in the sheet resistance, owing to this improvement in the electron mobility, can be attained. This reduction in sheet resistance leads to a reduction in the on-resistance of the power MISFETQ₅. As a result, a power amplifier having this power MISFETQ₅ mounted thereon has an improved efficiency.

### Embodiment 9

In Embodiment 9, an example in which the distance between the gate electrode 30 and strained silicon layer 35 is widened compared with that in Embodiment 1 will be explained.

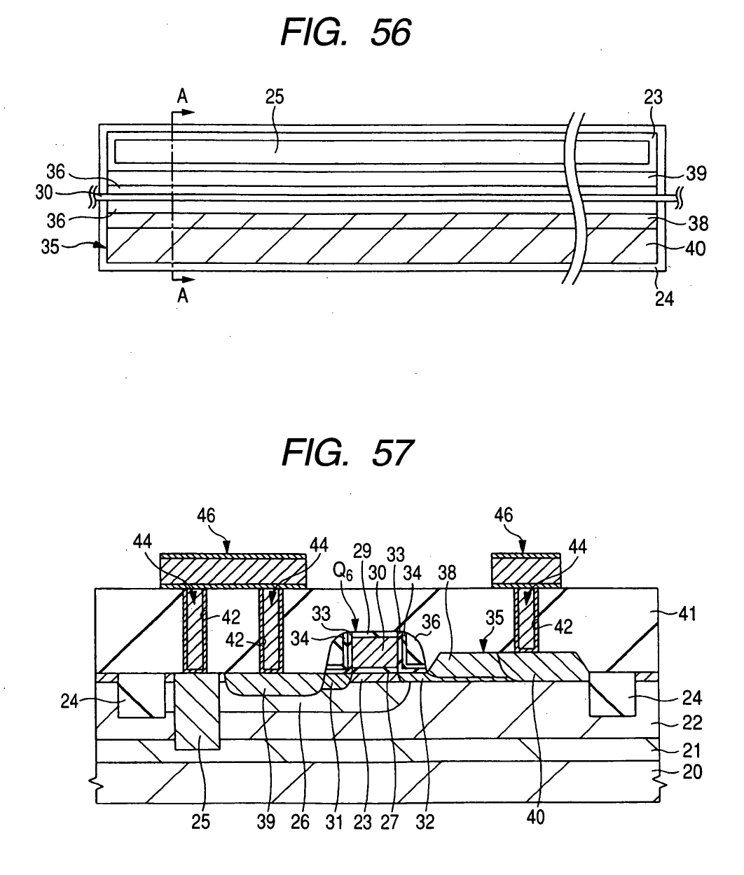

FIG. 56 is a plan view mainly illustrating a power MISFETQ₆ according to Embodiment 9. FIG. 56 is almost similar to FIG. 2, which is a plan view of the power MISFETQ₁ in Embodiment 1, so that only the difference between them will be described.

A difference of FIG. 56 from FIG. 2 resides in the fact that the distance between the strained silicon layer 35 formed in the drain region and the gate electrode 30 is wider than that in Embodiment 1.

FIG. 57 is a cross-sectional view taken along a line A-A of FIG. 41. FIG. 57 is almost similar to FIG. 3 which is a cross-sectional view of the power MISFETQ₁ in Embodiment 1. As is apparent from FIG. 57, the strained silicon layer 35 is formed outside of the side walls 36 formed over the side surfaces of the gate electrode 30. In Embodiment 1, as illustrated in FIG. 3, the strained silicon layer 35 is formed as if it embeds itself in the side walls 36. Accordingly, the distance between the strained silicon layer 35 and gate electrode 30 in Embodiment 9 is wider than that between the strained silicon layer 35 and gate electrode in Embodiment 1. According to Embodiment 9, the feedback capacitance generated between the gate electrode 30 and the strained silicon layer 35 can be reduced, leading to an improvement of the electrical properties of the power MISFETQ₆.

A method of manufacture of the power MISFETQ₆ according to Embodiment 9 will be described next with reference to the drawings.

Steps similar to FIG. 8 to FIG. 15 of Embodiment 1 are carried out. After formation of a silicon oxide film over the main surface of the semiconductor substrate 20, anisotropic dry etching of this silicon oxide film is conducted to form side walls 36 over the side surfaces of the gate electrode 30, as illustrated in FIG. 58.

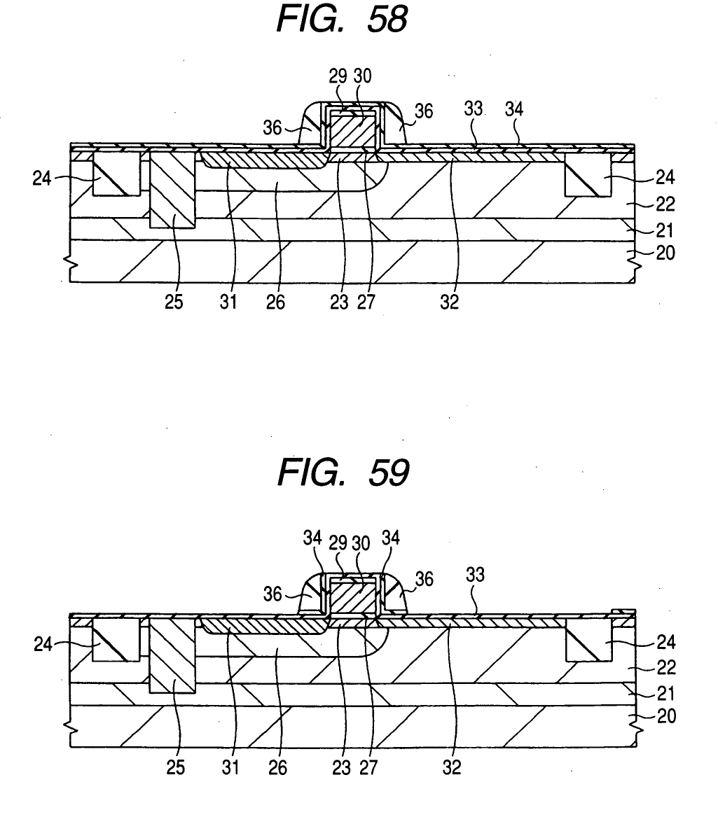

The silicon nitride film 34 is then patterned as illustrated in FIG. 59 by using photolithography and anisotropic dry etching. This patterning is conducted to remove the silicon nitride film 34 formed in the drain formation region outside the side walls 36.

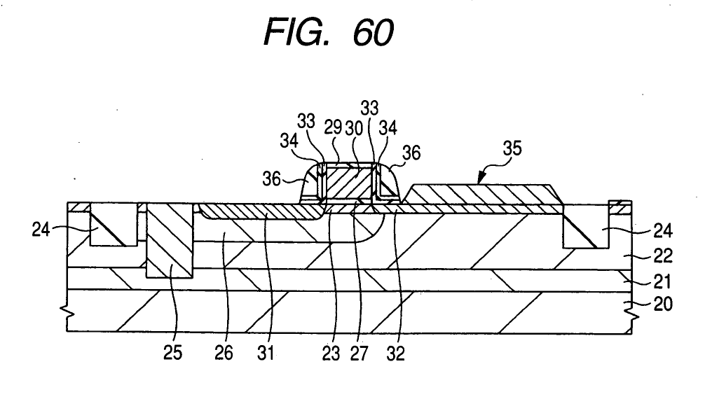

Using the patterned silicon nitride film 34 as a mask, the silicon oxide film 33 in the drain formation region is removed by wet etching to expose the strained silicon layer 23 (lightly-doped n type impurity diffusion region 32) over the drain formation region. After removal of the patterned silicon nitride film 34, a strained silicon layer 35 of about 40 nm in thickness is selectively formed over the strained silicon layer 23 (lightly-doped n type impurity diffusion region 32) exposed over the drain formation region, as illustrated in FIG. 60. This strained silicon layer 35 is formed, for example, by the selective epitaxial growth.

In Embodiment 9, since the strained silicon layer 35 is formed over the drain region after the formation of the side walls 36 over the side surfaces of the gate electrode 30, the distance between the strained silicon layer 35 and the gate electrode 30 becomes greater than the width of the side walls. The distance between the strained silicon layer 35 and gate electrode 30 can be made wider than that of Embodiment 1 in which the strained silicon layer 35 is formed to embed itself in the side walls. This makes it possible to reduce the feedback capacitance generated between the gate electrode 30 and the strained silicon layer 35, leading to an improvement in the electrical properties of the power MISFETQ₆.

Subsequent steps are similar to those of Embodiment 1, as illustrated in FIGS. 20 and 21. Finally, as illustrated in FIG. 57, the MISFETQ₆ having a relatively widened distance between the strained silicon layer 35 and gate electrode 30 can be formed.

Similar to Embodiment 1, in Embodiment 9, large portions of the offset region 38 and heavily-doped n type impurity diffusion region 40 are formed in the strained silicon layer 23 and strained silicon layer 35, each having a higher electron mobility, so that a drastic reduction in the sheet resistance can be attained owing to an improvement in the electron mobility. This reduction in sheet resistance leads to a reduction in the on-resistance of the power MISFETQ₆. As a result, a power amplifier having this power MISFETQ₆ mounted thereon has an improved efficiency.

The invention made by the present inventors has been described specifically based on some embodiments. It should however be borne in mind that the present invention is not limited to or by them. It is needless to say that the invention can be modified to an extent not departing from the scope of the invention. In other words, the invention is not limited to a semiconductor device to be mounted on an RF (Radio Frequency) power module, but can be modified to an extent not departing from the scope of the present invention. The present invention can be used widely in the manufacture of semiconductor devices.

1-15. (canceled)

16. A manufacturing method of a semiconductor device, comprising the steps of:
(a) preparing a semiconductor substrate by forming a silicon-germanium layer thereover and then, forming a first silicon layer having a strain over the silicon-germanium layer;
(b) forming a gate insulating film over the first silicon layer;
(c) forming a gate electrode over the gate insulating film;
(d) after the step (c), forming a second silicon layer having a strain over a drain formation region of the first silicon layer; and
(e) introducing an impurity into the second silicon layer.

17. A manufacturing method of a semiconductor device according to claim 16, wherein in the step (d), the second silicon layer is formed using selective epitaxial growth.

18. A manufacturing method of a semiconductor device according to claim 16, further comprising, after the step (a) but prior to the step (b), a step of forming an element isolation region for separating between elements.

19. A manufacturing method of a semiconductor device according to claim 16, further comprising after the step (a) but prior to the step (b), a step of forming a well.

20. A manufacturing method of a semiconductor device according to claim 16, wherein in the step (d), the second silicon layer having a strain is formed over almost the whole region of the drain formation region of the first silicon layer.

21. A manufacturing method of a semiconductor device according to claim 16, wherein in the step (d), the second silicon layer having a strain is formed over a portion of the drain formation region of the first silicon layer.

22. A manufacturing method of a semiconductor device according to claim 16, wherein in the step (d), the second silicon layer having a strain is formed over a source formation region of the first silicon layer in addition to the drain formation region.

23. A manufacturing method of a semiconductor device according to claim 16, wherein the second silicon layer formed by the step (d) is divided into plural sections in an extending direction of the gate electrode.

24. A manufacturing method of a semiconductor device, comprising the steps of:
(a) preparing a semiconductor substrate by forming a silicon-germanium layer thereover and then, forming a first silicon layer having a strain over the silicon-germanium layer;
(b) forming an element isolation region for separating between elements over the silicon-germanium layer and the first silicon layer;
(c) forming a gate insulating film over the first silicon layer;
(d) forming a gate electrode over the gate insulating film;
(e) after the step (d), forming an insulating film over the first silicon layer;
(f) after the step (e), patterning the insulating film to leave the insulating film formed over the vicinity of a portion of the first silicon layer on the side of the drain region which portion is contiguous to the element isolation region; and
(g) after the step (f), forming a second silicon layer having a strain over a portion of the first silicon layer on the side of the drain region from which the insulating film has been removed.

25. A manufacturing method of a semiconductor device, comprising the steps of:
(a) preparing a semiconductor substrate by forming a silicon-germanium layer thereover and then, forming a first silicon layer having a strain over the silicon-germanium layer;
(b) forming a gate insulating film over the first silicon layer;
(c) forming a gate electrode over the gate insulating film;
(d) forming a lightly-doped drain region on one side in alignment with the gate electrode;
(e) forming, outside of the lightly-doped drain region, a heavily-doped drain region which has a higher impurity concentration than that of the lightly-doped drain region, and forming a heavily-doped source region on the opposite side relative to the gate electrode; and
(f) after the step (e), forming an insulating film which has been opened at a portion over the lightly-doped drain region; and
(g) after the step (f), forming a second silicon layer containing an impurity and having a strain over the lightly-doped drain region.

26. A manufacturing method of a semiconductor device, comprising the steps of:
(a) preparing a semiconductor substrate by forming a silicon-germanium layer thereover and then, forming a first silicon layer having a strain over the silicon-germanium layer;
(b) forming a gate insulating film over the first silicon layer;
(c) forming a gate electrode over the gate insulating film;
(d) forming side walls over the side surfaces of the gate electrode; and
(e) after the step (d) forming, over the drain formation region of the first silicon layer outside of the side walls, a second silicon layer having a strain.
